(19) United States
(12) Patent Application Publication
(10) Pub. No.: US 2016/0276276 A1
(43) Pub. Date: Sep. 22, 2016

(54) SEMICONDUCTOR DEVICE

(71) Applicant: Kabushiki Kaisha Toshiba, Minato-ku (JP)

(72) Inventors: Yusuke ARAYASHIKI, Yokkaichi (JP); Kikuko SUGIMAE, Kuwana (JP); Takuya Konno, Yokkaichi (JP); Masayuki Ichige, Yokkaichi (JP)

(73) Assignee: Kabushiki Kaisha Toshiba, Minato-ku (JP)

(21) Appl. No.: 14/796,526

(22) Filed: Jul. 10, 2015

Related U.S. Application Data
(60) Provisional application No. 62/135,420, filed on Mar. 19, 2015.

(51) Int. Cl. H01L 23/538

(52) U.S. Cl. CPC H01L 23/5383

(57) ABSTRACT

According to one embodiment, a semiconductor device includes a substrate; a first interconnect portion provided on the substrate and including a plurality of interconnect layers separately stacked each other; a second interconnect portion provided separately from the first interconnect portion on the substrate and including the plurality of interconnect layers having a number of stacked layers same as a number of stacked layers of the first interconnect portion; a first pillar provided adjacent to the first interconnect portion and the second interconnect portion and extending in a stacking direction of the plurality of interconnect layers; and a plurality of conductive layers. The plurality of conductive layers is separately stacked each other, surrounding a side surface of the first pillar, and electrically connected to the first interconnect portion and the second interconnect portion.

This application is based upon and claims the benefit of priority from U.S. Provisional Patent Application 62/135,420 field on Mar. 19, 2015; the entire contents of which are incorporated herein by reference.

### FIELD

Embodiments described herein relate generally to a semiconductor device.

### BACKGROUND

In a semiconductor device, the structure of stacked interconnects could be a cause of hindrance of refining of the device. Therefore, a reduction in the stacked interconnects is an example of an object.

### BRIEF DESCRIPTION OF THE DRAWINGS

FIG. 1A is a schematic sectional view of a stacked structure of a semiconductor device of a first embodiment, and FIGS. 1B to 1F are schematic plan views of the semiconductor device;

FIG. 2A to FIG. 8C are schematic views showing a method for manufacturing the semiconductor device of the first embodiment;

FIGS. 9A to 9E are schematic views showing an example of a layout of the semiconductor device of the first embodiment;

FIG. 10A is a schematic perspective view of a memory cell portion of a semiconductor device of a second embodiment, and FIG. 10B is a circuit diagram of the memory cell portion;

FIG. 11A is a schematic plan view of the semiconductor device of the second embodiment, FIG. 11B is an enlarged schematic plan view of a part of a stacked structure of the semiconductor device, and FIGS. 11C and 11D are schematic sectional views of a part of a stacked structure of the semiconductor device;

FIG. 12A to FIG. 18C are schematic views showing a method for manufacturing the semiconductor device of the second embodiment;

FIGS. 19A to 19D are schematic plan views showing an example of a layout of the semiconductor device of the second embodiment;

FIG. 20A is an enlarged schematic sectional view of a part of a stacked structure of the semiconductor device of a third embodiment, FIGS. 20B and 20C are enlarged schematic plan views of a part of the stacked structure of the semiconductor device;

FIG. 21A is an enlarged schematic sectional view of a part of a stacked structure of the semiconductor device of the third embodiment, FIGS. 21B and 21C are enlarged schematic plan views of a part of the stacked structure of the semiconductor device; and

FIG. 22A is an enlarged schematic sectional view of a part of a stacked structure of the semiconductor device of the third embodiment, FIGS. 22B and 22C are enlarged schematic plan views of a part of the stacked structure of the semiconductor device.

### DETAILED DESCRIPTION

According to one embodiment, a semiconductor device includes a substrate; a first interconnect portion provided on the substrate and including a plurality of interconnect layers separately stacked each other; a second interconnect portion provided separately from the first interconnect portion on the substrate and including the plurality of interconnect layers having a number of stacked layers same as a number of stacked layers of the first interconnect portion; a first pillar provided adjacent to the first interconnect portion and the second interconnect portion and extending in a stacking direction of the plurality of interconnect layers; and a plurality of conductive layers. The plurality of conductive layers is separately stacked each other, surrounding a side surface of the first pillar, and electrically connected to the first interconnect portion and the second interconnect portion.

Embodiments are described below with reference to the drawings. Note that, in the drawings, the same components are denoted by the same reference numerals and signs.

### First Embodiment

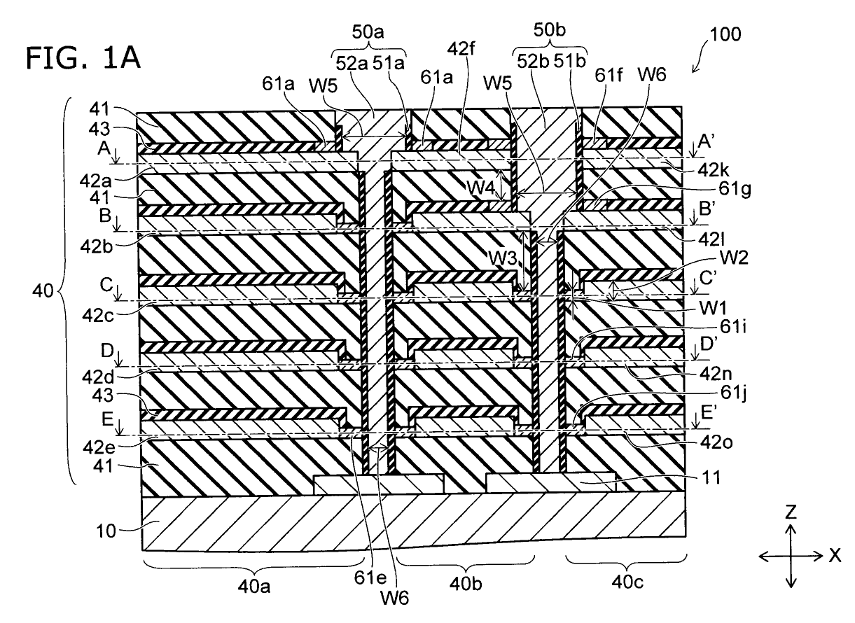

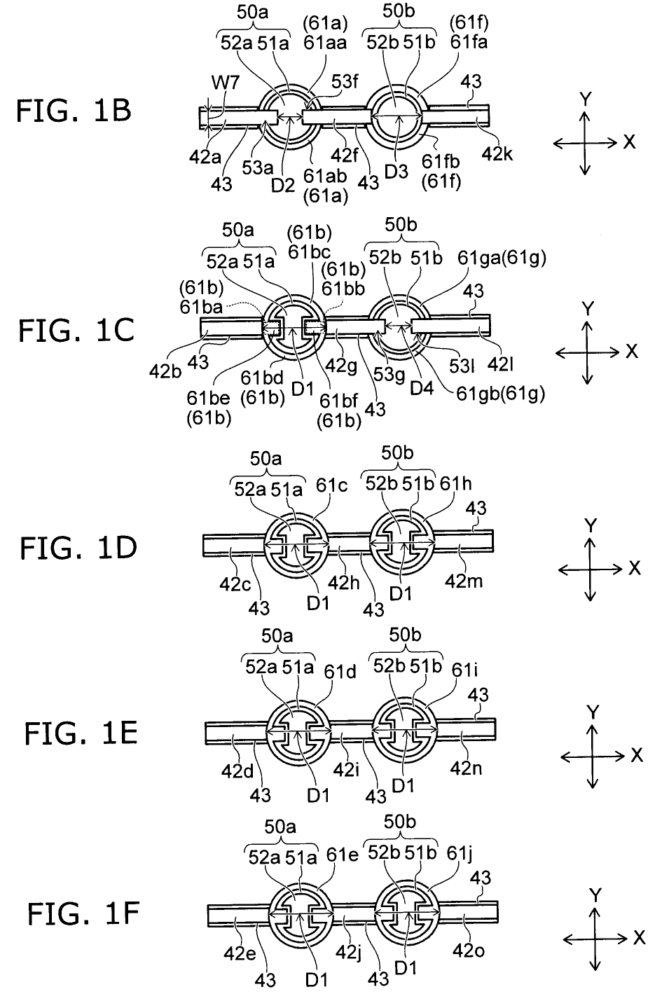

FIG. 1A is a schematic sectional view of a stacked structure 100 of a semiconductor device in a first embodiment. FIGS. 1B to 1F are schematic plan views corresponding to lines A-A′, B-B′, C-C′, D-D′, and E-E′ in FIG. 1A.

Note that the stacked structure 100 includes a purpose of interconnect in the semiconductor device. For example, the stacked structure 100 may be used as an interconnect that connects a memory cell portion described below and a control portion. A form of an element (e.g., a memory cell or an image sensor) connected to the stacked structure 100 is optional.

In FIG. 1A, two directions parallel to a major surface of a substrate 10 and orthogonal to each other are represented as an X-direction and a Y-direction. A direction orthogonal to the X-direction and the Y-direction is represented as a Z-direction (a stacking direction).

The stacked structure 100 of the embodiment is described with reference to FIGS. 1A to 1F.

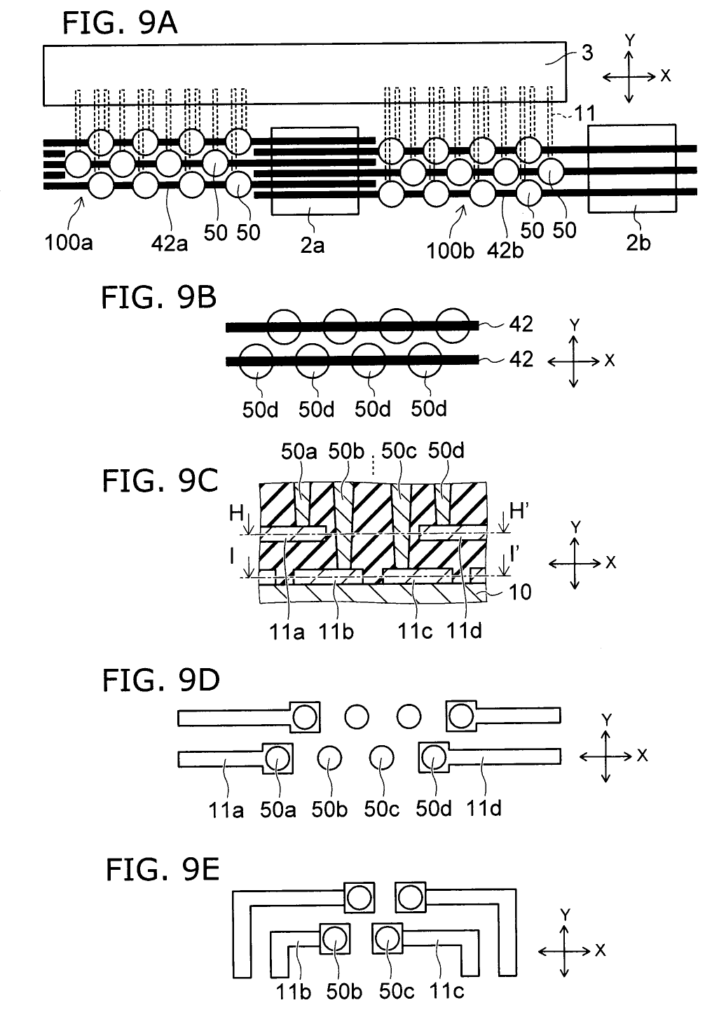

As shown in FIG. 1A, in the stacked structure 100 of the embodiment, a stacked body 40 is provided on the substrate 10. Insulating layers 41 are provided in a top layer and a bottom layer of the stacked body 40. The substrate 10 includes an interconnect portion connected to a control portion (e.g., a control portion 3 shown in FIG. 9A).

The stacked body 40 includes a first interconnect portion 40a, a second interconnect portion 40b, and a third interconnect portion 40c. The interconnect portions 40a, 40b, and 40c are provided separately from one another.

The interconnect portions 40a, 40b, and 40c include insulating layers 41 and 43 and interconnect layers 42a to 42o. Note that, when the interconnect layers 42a to 42o are not distinguished, the interconnect layers 42a to 42o are simply referred to as interconnect layers 42. In FIG. 1A, reference signs of the interconnect layers 42g to 42j are not shown for the sake of clarity of the drawing.

In the first interconnect portion 40a, the interconnect layers 42a to 42e are provided in order from upper layers to lower layers. As in the first interconnect portion 40a, in the second interconnect portion 40b, the interconnect layers 42f to 42j are provided. In the third interconnect portion 40c, the interconnect layers 42k to 42o are provided. That is, the interconnect portions 40a, 40b, and 40c respectively include the same number of stacked interconnect layers 42.

The interconnect layers 42a, 42f, and 42k provided at the top layer are provided separately from one another in substantially the same distances from the substrate 10. The same applies to the interconnect layers 42b, 42g, and 42l, the interconnect layers 42c, 42h, and 42m, the interconnect layers 42d, 42i, and 42n, and the interconnect layers 42e, 42j, and 42o.

That is, the interconnect layers 42 are stacked via the insulating layers 41 and extend in the X-direction (a first direction). The interconnect layers 42a to 42e are separated from each other in the Z-direction. Side surfaces of the interconnect layers 42 parallel to an extending direction of the interconnect layers 42 or the X-direction are in contact with the insulating layers 43.

The interconnect layers 42 include, for example, metal (tungsten). The insulating layers 43 include a material different from the material of the insulating layers 41. For example, the insulating layers 43 include a silicon nitride film.

A pillar 50a extending in the stacking direction (the Z-direction) is provided adjacently between the first interconnect portion 40a and the second interconnect portion 40b. The pillar 50a includes a contact portion 52a and an insulating film 51a.

The contact portion 52a continuously extends in the Z-direction and is in contact with a lower layer interconnect 11. The contact portion 52a has, for example, a columnar shape. Note that the columnar shape includes a cylinder or an elliptic cylinder.

The contact portion 52a is in contact with the interconnect layers 42a and 42f. In the X-direction, a maximum diameter W5 of the contact portion 52a above the interconnect layers 42a and 42f is larger than a maximum diameter W6 of the contact portion 52a below the interconnect layers 42a and 42f.

The insulating film 51a is provided between the contact portion 52a and the interconnect portions 40a and 40b.

The insulating film 51a is in contact with the contact portion 52a and continuously extends in the Z-direction. The insulating film 51a covers the side surface of the contact portion 52a and has, for example, a ring shape.

The insulating film 51a is in contact with the upper surfaces of the interconnect layers 42a and 42f. The insulating film 51a is separated from the interconnect layers 42 below the interconnect layers 42a and 42f. The upper surfaces of the interconnect layers 42a and 42f are in contact with the contact portion 52a.

A pillar 50b extending in the Z-direction is provided adjacently between the second interconnect portion 40b and the third interconnect portion 40c. The pillar 50b includes a contact portion 52b and an insulating film 51b.

The contact portion 52a continuously extends in the Z-direction and is in contact with the lower layer interconnect 11. The contact portion 52a has, for example, a columnar shape.

The contact portions 52b is in contact with the interconnect layers 42g and 42l. In the X-direction, the maximum diameter W5 of the contact portion 52b above the interconnect layers 42g and 42l is larger than the maximum diameter W6 of the contact portion 52b below the interconnect layers 42g and 42l.

The insulating film 51b is provided between the contact portion 52b and the interconnect portions 40b and 40c. The insulating film 51b is in contact with the contact portion 52b and continuously extends in the Z-direction. The insulating film 51b covers the side surface of the contact portion 52b and has, for example, a ring shape.

The insulating film 51b is in contact with the upper surfaces of the interconnect layers 42g and 42l, the upper surfaces of the interconnect layers 42g and 42l are in contact with the contact portion 52b. The insulating film 51b is in contact with side surfaces parallel to the Y-direction of the interconnect layers 42f and 42k, the interconnect layers 42f and 42k is provided on the interconnect layers 42g and 42l. The insulating film 51b is separated from the interconnect layer 42 below the interconnect layers 42g and 42l.

Conductive layers 61a to 61j are separately provided each other between the interconnect portions 40a, 40b, and 40c and the pillars 50a and 50b. Note that when it is unnecessary to distinguish the conductive layers 61a to 61j, the conductive layers 61a to 61j are simply referred to as conductive layers 61.

The conductive layers 61 are in contact with the insulating films 51a and 51b. The conductive layers 61 cover the side surfaces of the insulating films 51a and 51b and have, for example, a ring shape. Thickness W1 in the Z-direction of the conductive layers 61 is smaller than thickness W2 of the interconnect layers 42.

The conductive layer 61a is in contact with the upper surfaces of the interconnect layers 42a and 42f, which are in contact with the contact portion 52a. A side surface of the conductive layer 61a is in contact with the insulating layer 43.

The conductive layers 61b to 61e are provided below the conductive layer 61a. The conductive layers 61b to 61e are respectively in contact with the insulating film 51a and the interconnect layers 42b to 42e and 42g to 42j. The conductive layers 61b to 61e are respectively provided between the insulating film 51a and the interconnect layers 42b to 42e and 42g to 42j. The upper surfaces of the conductive layers 61b to 61e are in contact with the insulating layers 43.

The conductive layer 61g is in contact with the upper surfaces of the interconnect layers 42g and 42l, the upper surfaces of the interconnect layers 42g and 42l are in contact with the contact portion 52b. The side surface of the conductive layer 61g is in contact with the insulating layers 43.

The conductive layers 61h to 61j provided below the conductive layer 61g are respectively in contact with and provided between the insulating film 51b and the interconnect layers 42h to 42j and 42m to 42o. The upper surfaces of the conductive layers 61h to 61j are in contact with the insulating layers 43.

The conductive layer 61f provided above the conductive layer 61g is in contact with the upper surfaces of the interconnect layers 42f and 42k. The side surface of the conductive layer 61f is in contact with the insulating layers 43.

A distance W4 between the conductive layer 61g and the interconnect layer 42f is smaller than a distance W3 between the conductive layer 61h and the interconnect layer 42g under the conductive layer 61g and the interconnect layer 42f. The conductive layers 61 contain the same material, for example, tungsten.

As described above, the maximum diameters in the X-direction of the contact portions 52a and 52b are different above and below the interconnect layers 42 that are in contact with the contact portions 52a and 52b.

The insulating films 51a and 51b are in contact with the upper surfaces of first parts of interconnect layers 42. The first parts of interconnect layers 42 are in contact with the contact portions 52a and 52b. The insulating films 51a and 51b are separated from second parts of interconnect layers 42. The second parts of interconnect layers 42 are provided below the first parts of interconnect layers 42. The insulating films 51a and 51b are in contact with side surfaces parallel to the Y-direction of third parts of interconnect layers 42. The third parts of interconnect layers 42 are provided on the first parts of interconnect layers 42.

Further, the conductive layers 61 are in contact with the upper surfaces of the first parts of interconnect layers 42 and the upper surfaces of the second parts of interconnect layers 42. The side surfaces of the conductive layers 61 are in contact with the insulating layers 43. Parts of conductive layers 61 is provided below the first parts of interconnect layers 42. The parts of conductive layers 61 are respectively in contact with the second parts of interconnect layers 42 and the insulating films 51a and 51b. The parts of conductive layers 61 is respectively provided between the second parts of interconnect layers 42 and the insulating films 51a and 51b. The upper surfaces of the parts of conductive layers 61 are in contact with the insulating layers 43.

In addition to the above, parts of insulating layers 43 are provided below the first parts of interconnect layers 42. The parts of insulating layers 43 are in contact with the side surfaces parallel to the Y-direction of the second parts of interconnect layers 42.

The shapes around the pillars 50a and 50b are described with reference to FIGS. 1B to 1F.

As shown in FIG. 1B, the contact portion 52a is in contact with end portions 53a and 53f of the interconnect layers 42a and 42f. The interconnect layer 42a is separated from the interconnect layer 42f in the X-direction by a distance D2.

The interconnect layer 42a is electrically connected to the interconnect layer 42f via the conductive layer 61a. The conductive layer 61a is in contact with side surface of the interconnect layers 42a and 42f. The conductive layer 61a extends along the side surface of the insulating film 51a. The insulating film 51a is in contact with the interconnect layers 42a and 42f and the conductive layer 61a.

The conductive layer 61a includes periphery portions 61aa and 61ab.

The periphery portion 61aa is in contact with side surfaces of the interconnect layers 42a and 42f. The side surfaces of the interconnect layers 42a and 42f are separated from the end portions 53a and 53f. The periphery portion 61aa extends along the side surface of the insulating film 51a.

The periphery portion 61ab is in contact with side surfaces opposed to side surfaces of the interconnect layers 42a and 42f being in contact with the periphery portion 61aa, the periphery portion 61ab extends along the side surface of the insulating film 51a. The periphery portion 61ab is separated from the periphery portion 61aa.

The insulating film 51a is in contact with and provided integrally with the end portions 53a and 53f and the periphery portions 61aa and 61ab.

The contact portion 52b is separated from the interconnect layers 42f and 42k. The interconnect layer 42f is separated from the interconnect layer 42k in the X-direction by a distance D3.

The interconnect layer 42f is electrically connected to the interconnect layer 42k via the conductive layer 61f. The conductive layer 61f is in contact with side surface of the interconnect layers 42f and 42k. The conductive layer 61f extends along the side surface of the insulating film 51b. The insulating film 51b is in contact with the interconnect layers 42f and 42k and the conductive layer 61f.

The conductive layer 61f includes periphery portions 61fa and 61fb.

The periphery portion 61fa is in contact with side surfaces parallel to the X-direction of the interconnect layers 42f and 42k, and extends along the side surface of the insulating film 51b.

The periphery portion 61fb is in contact with side surfaces opposed to side surfaces of the interconnect layers 42f and 42k being in contact with the periphery portion 61fa, the periphery portion 61fb extends along the side surface of the insulating film 51b. The periphery portion 61fb is separated from the periphery portion 61fa.

The insulating film 51b is in contact with and provided integrally with the interconnect layers 42f and 42k and the periphery portions 61fa and 61fb. The insulating film 51b is in contact with side surfaces parallel to the Y direction of the interconnect layers 42f and 42k.

As shown in FIG. 1C, the contact portion 52a is separated from the interconnect layers 42b and 42g. The interconnect layer 42b is separated from the interconnect layer 42g in the X-direction by a distance D1.

The interconnect layer 42b is electrically connected to the interconnect layer 42g via the conductive layer 61b. The conductive layer 61b is in contact with side surface of the interconnect layers 42b and 42g. The conductive layer 61b extends along the side surface of the insulating film 51a. The insulating film 51a is in contact with the interconnect layers 42b and 42g and the conductive layer 61b.

The conductive layer 61b includes connecting portions 61ba and 61bb, and periphery portions 61bc and 61bd.

The connecting portions 61ba is in contact with a side surface parallel to the Y-direction of the interconnect layer 42b. The connecting portion 61bb is in contact with a side surface parallel to the Y-direction of the interconnect layer 42g. The connecting portion 61bb is separated from the connecting portion 61ba in the X-direction.

The periphery portion 61bc is in contact with the connecting portions 61ba and 61bb and extends along the side surface of the insulating film 51a.

The periphery portion 61bd is in contact with side surfaces opposed to side surface of the connecting portions 61ba and 61bb being in contact with the periphery portion 61bc, the periphery portion 61bd extends along the side surface of the insulating film 51a. The periphery portion 61bd is separated from the periphery portion 61bc.

The connecting portion 61ba includes an end portion 61be (first distal end portion). The end portion 61be extends in the X-direction. The end portion 61be is separated from the connecting portion 61bb and the periphery portions 61bc and 61bd.

The connecting portion 66bb includes an end portion 61bf (second distal end portion). The end portion 61bf extends in the X-direction. The end portion 61bf is separated from the periphery portions 61bc and 61bd and the end portion 61be.

The insulating film 51a is in contact with and provided integrally with the periphery portions 61bc and 61bd and the end portions 61be and 61bf. That is, the insulating film 51a is in contact with and provided integrally with the interconnect layers 42a and 42f, the periphery portions 61aa, 61ab, 61bc, and 61bd, and the end portions 61be and 61bf.

The contact portion 52b is in contact with end portions 53g and 531 of the interconnect layers 42g and 42l. The interconnect layer 42g is separated from the interconnect layer 42l in the X-direction by a distance D4.

The interconnect layer 42g is electrically connected to the interconnect layer 42l via the conductive layer 61g. The conductive layer 61g is in contact with side surface of the interconnect layers 42g and 42l. The conductive layer 61g extends along the side surface of the insulating film 51b. The insulating film 51b is in contact with the interconnect layers 42g and 42l and the conductive layer 61g.

The conductive layer 61g includes periphery portions 61ga and 61gb.

The periphery portion 61ga is in contact with side surfaces of the interconnect layers 42g and 42l. The side surfaces of the interconnect layers 42g and 42l are separated from the end portions 53g and 53l. The periphery portion 61ga extends along the side surface of the insulating film 51b.

The periphery portion 61gb is in contact with side surfaces opposed to side surfaces of the interconnect layers 42g and 42l being in contact with the periphery portion 61ga, the periphery portion 61gb extends along the side surface of the insulating film 51b. The periphery portion 61gb is separated from the periphery portion 61ga.

The insulating film 51b is in contact with and provided integrally with the interconnect layers 42g and 42l and the periphery portions 61ga and 61gb. That is, the insulating film 51b is provided in contact with and integral with the interconnect layers 42f, 42g, 42k, and 42l and the periphery portions 61fa, 61fb, 61ga, and 61gb.

Note that the distance D1 is larger than the distance D2 and the distance D3 is larger than the distance D4. For example, the distance D1 may be equal to the distance D3, and the distance D2 may be equal to the distance D4.

As shown in FIGS. 1D to 1F, the configurations of the contact portions 52a and 52b and the peripheries thereof are the same as the configurations of the contact portion 52a and the periphery thereof shown in FIG. 1C described above. Therefore, description of the configurations is omitted.

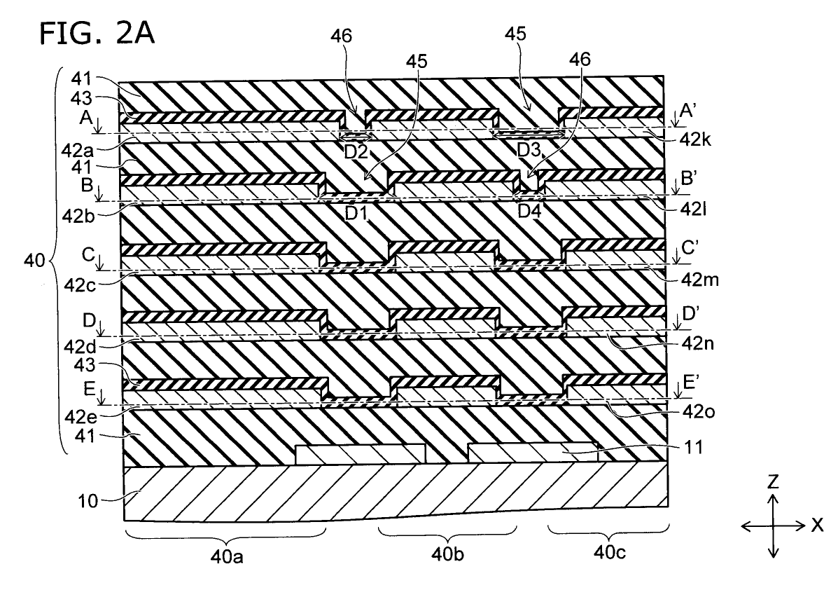

A method of manufacturing a semiconductor device of the embodiment is described with reference to FIGS. 2A to 8C.

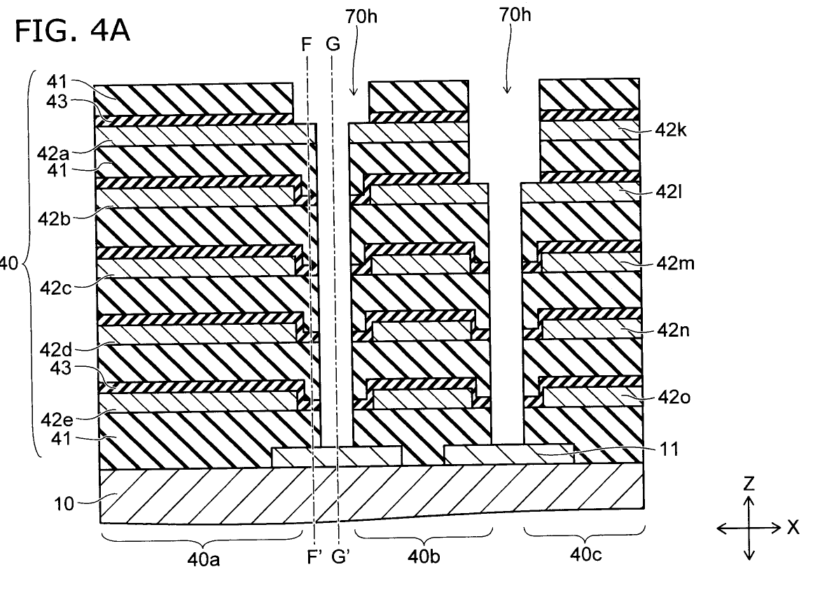

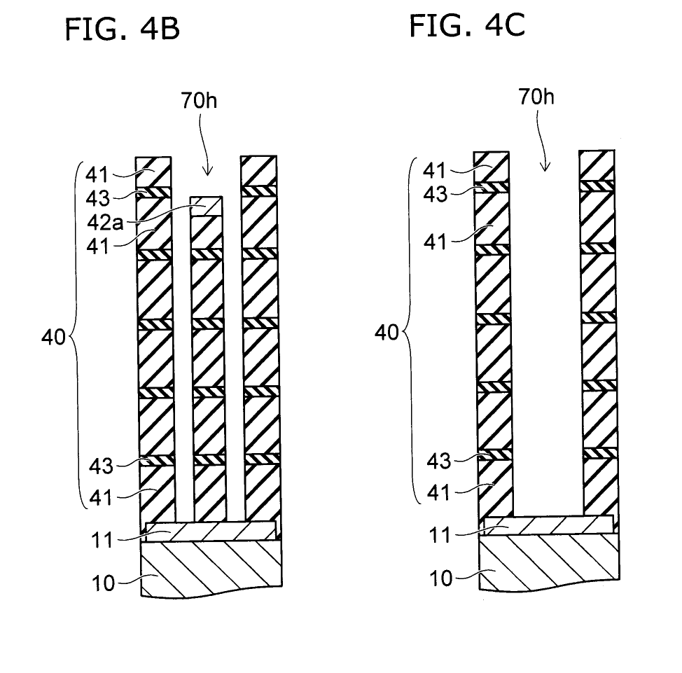

FIGS. 2A, 3, 4A, 5A, 6A, 7A, and 8A are schematic sectional views. FIGS. 2B to 2F are schematic plan views corresponding to lines A-A′, B-B′, C-C′, D-D′, and E-E′ in FIG. 2A. FIGS. 4B, 5B, 6B, 7B, and 8B are schematic sectional views corresponding to lines F-F′ in FIGS. 4A, 5A, 6A, 7A, and 8A. FIGS. 4C, 5C, 6C, 7C, and 8C are schematic sectional views corresponding to lines G-G′ in FIGS. 4A, 5A, 6A, 7A, and 8A.

As shown in FIGS. 2A to 2F, the lower layer interconnects 11 and the stacked body 40 are formed on the substrate 10. The stacked body 40 includes a plurality of insulating layers 41 and 43 and a plurality of interconnect layers 42.

As a method of forming the stacked body 40, for example, the insulating layers 41 are formed on the substrate 10. The interconnect layers 42 are formed on the insulating layers 41. The interconnect layers 42 are formed the distances D1 to D4 separated from one another in the X-direction. Thereafter, the insulating layers 43 are conformally formed on the upper surfaces of the interconnect layers 42 and between the interconnect layers 42. The insulating layers 41 are formed on the insulating layers 43. The insulating layers 41 are filled among the interconnect layers 42. The upper surfaces of the insulating layers 41 are uniformly formed on an XY plane.

The plurality of insulating layers 41, the plurality of interconnect layers 42, and the plurality of insulating layers 43 are formed in order.

As shown in FIG. 2B, the interconnect layer 42a and the interconnect layer 42f are formed the distance D2 separated from each other. The interconnect layer 42f and the interconnect layer 42k are formed the distance D3 separated from each other.

As shown in FIG. 2C, the interconnect layer 42b and the interconnect layer 42g are formed the distance D1 separated from each other. The interconnect layer 42g and the interconnect layer 42l are formed the distance D4 separated from each other.

As shown in FIG. 2D, the interconnect layer 42c and the interconnect layer 42h are formed the distance D1 separated from each other. The interconnect layer 42h and the interconnect layer 42m are formed the distance D1 separated from each other.

As shown in FIG. 2E, the interconnect layer 42d and the interconnect layer 42i are formed the distance D1 separated from each other. The interconnect layer 42i and the interconnect layer 42n are formed the distance D1 separated from each other.

As shown in FIG. 2F, the interconnect layer 42e and the interconnect layer 42j are formed the distance D1 separated from each other. The interconnect layer 42j and the interconnect layer 42o are formed the distance D1 separated from each other.

Thereafter, the stacked body 40 is formed by forming the insulating layer 41 in the top layer. The number of stacked layers of the stacked body 40 may be arbitrary. The stacked body 40 includes the first interconnect portion 40a, the second interconnect portion 40b, and the third interconnect portion 40c. Among the interconnect portions 40a, 40b, and 40c, spaces 45 of the distances D1 and D3 and spaces 46 of the distances D2 and D4 among the interconnect layers 40a to 40o are formed.

The interconnect layers 42 include metal such as tungsten. The insulating layers 41 include, for example, silicon oxide films. The insulating layers 43 include a material (e.g., silicon nitride films) different from the material of the insulating layers 41.

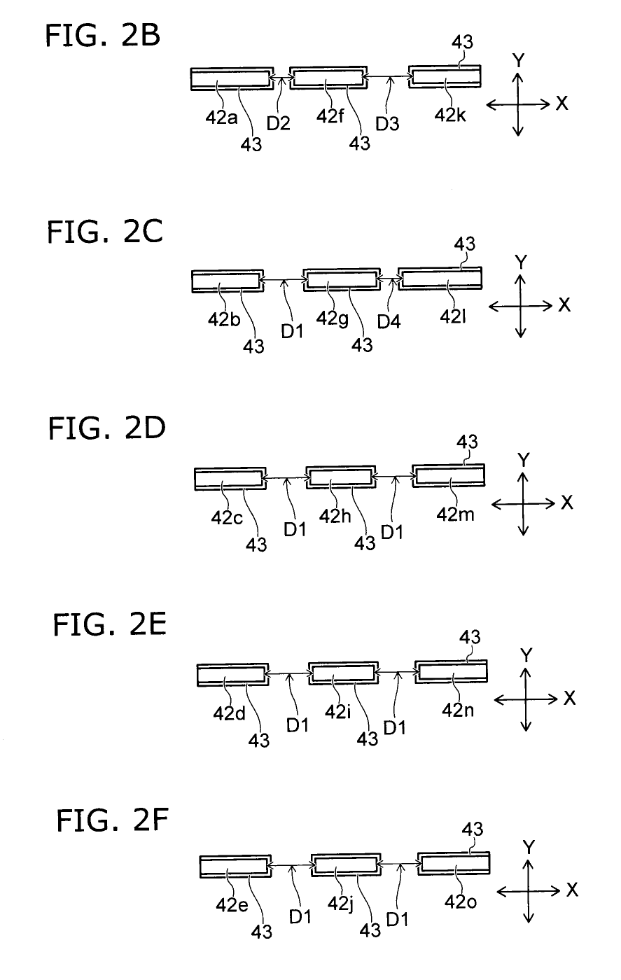

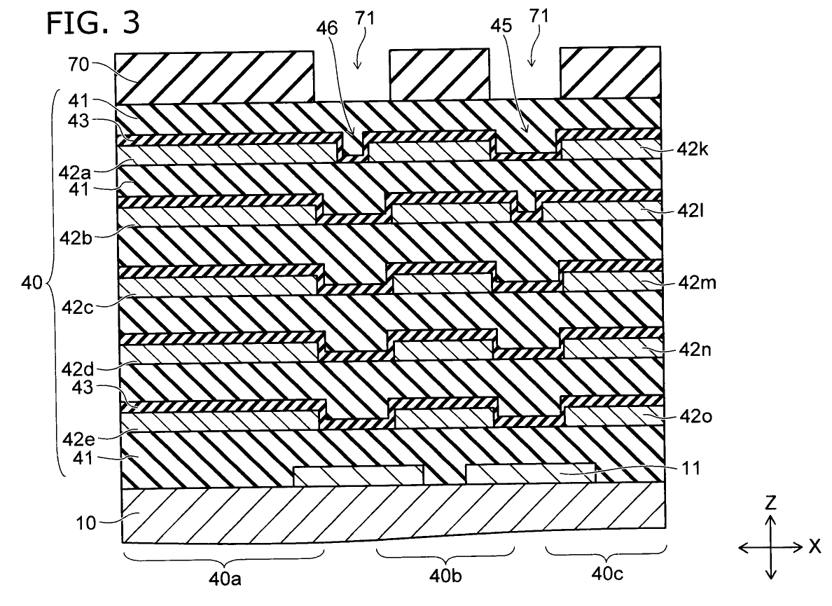

As shown in FIG. 3, a sacrificial film 70 is formed on the stacked body 40. Spaces 71 are formed on the spaces 45 and 46 of the stacked body 40. The width in the X-direction of the spaces 71 is, for example, the same as the width D1 of the space 45.

As shown in FIGS. 4A to 4C, holes 70h piercing through the stacked body 40 and reaching the lower layer interconnects 11 are formed. In the holes 70h, the side surfaces of the insulating layers 43 and the upper surfaces of the lower layer interconnects 11 are exposed. The side surfaces of the interconnect layers 42 in which the spaces 46 are formed and the side surfaces of the interconnect layers 42 above the interconnect layers 42 are exposed in the holes 70h. The interconnect layers 42 below the interconnect layers 42 in which the spaces 46 are formed are not exposed in the holes 70h. The holes 70h are formed by, for example, a RIE method (Reactive Ion Etching).

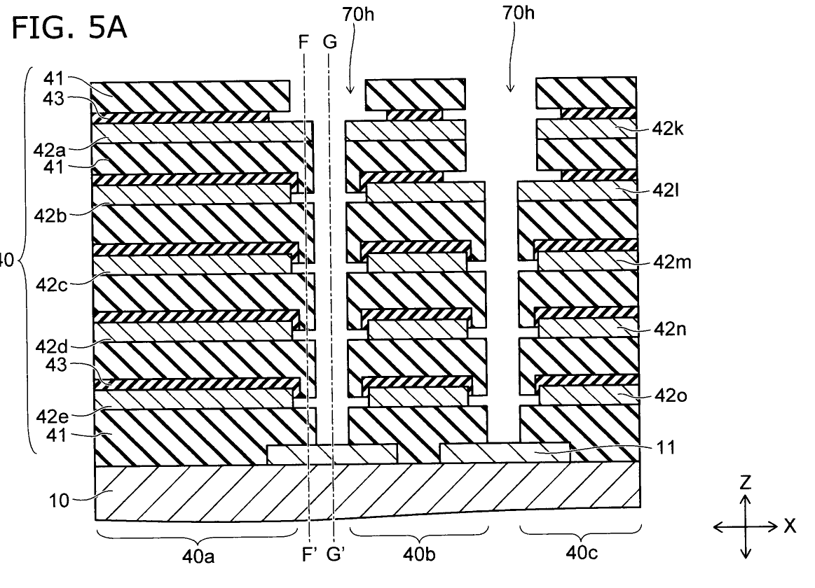

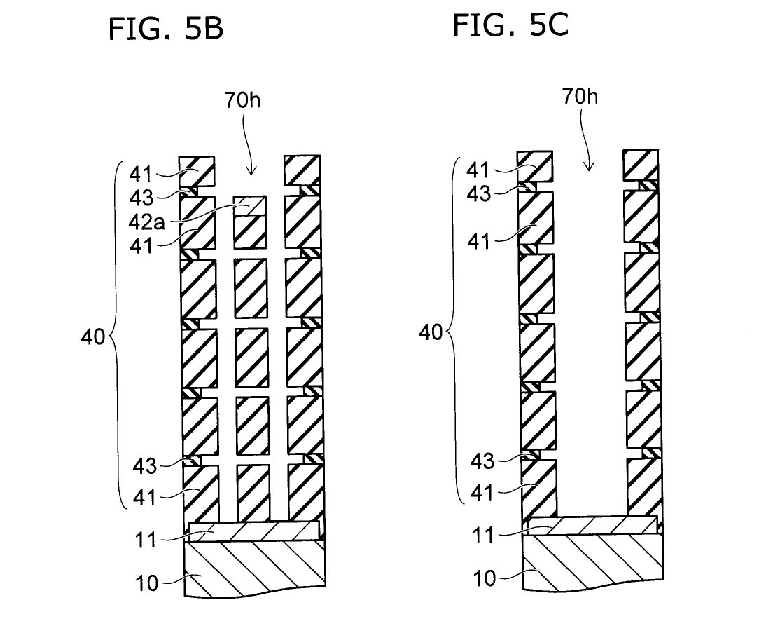

As shown in FIGS. 5A to 5C, the insulating layers 43 exposed in the holes 70h are retracted (etched back). Consequently, the interconnect layers 42 are exposed in the holes 70h.

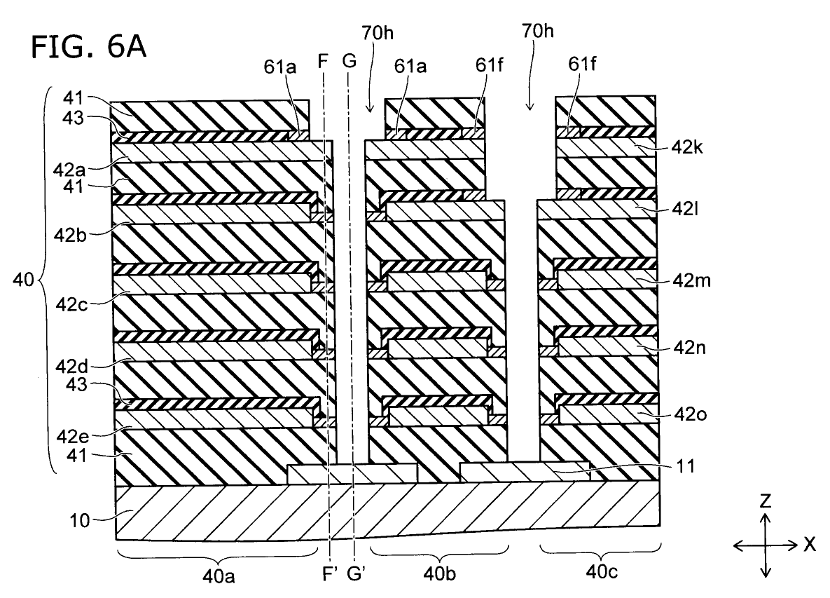

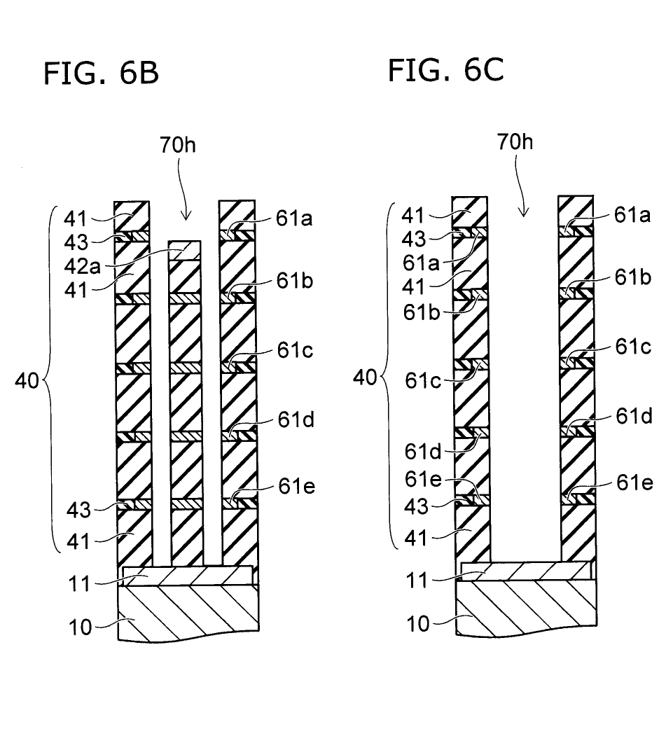

As shown in FIGS. 6A to 6C, a plurality of conductive layers 61 is formed in respective layers in retracted portions of the insulating layers 43. As a method of forming the conductive layers 61, for example, a CVD method (Chemical Vapor Deposition) is used to form films (e.g., titanium nitride) having electric conductivity in the retracted portions of the insulating layers 43 and the inner walls of the holes 70h through the holes 70h. Subsequently, for example, the CVD method is used to form metal films (e.g., tungsten) on the inner sides of the films having electric conductivity. Thereafter, the films formed on the interconnect layers 42 on both the sides of the spaces 46 are removed to expose the upper surfaces and the side surfaces of the interconnect layers 42 in the holes 70h. The films formed on the sidewalls and the like of the holes 70h are moved by, for example, etching using hydrochloric acid to form the conductive layers 61.

The plurality of conductive layers 61 is in contact with the interconnect layers 42 separated from each other across the holes 70h. Therefore, a pair of interconnect layers 42 separated from each other across the hole 70h is electrically connected via the conductive layers 61. The side surfaces of the conductive layers 61 are exposed in the holes 70h.

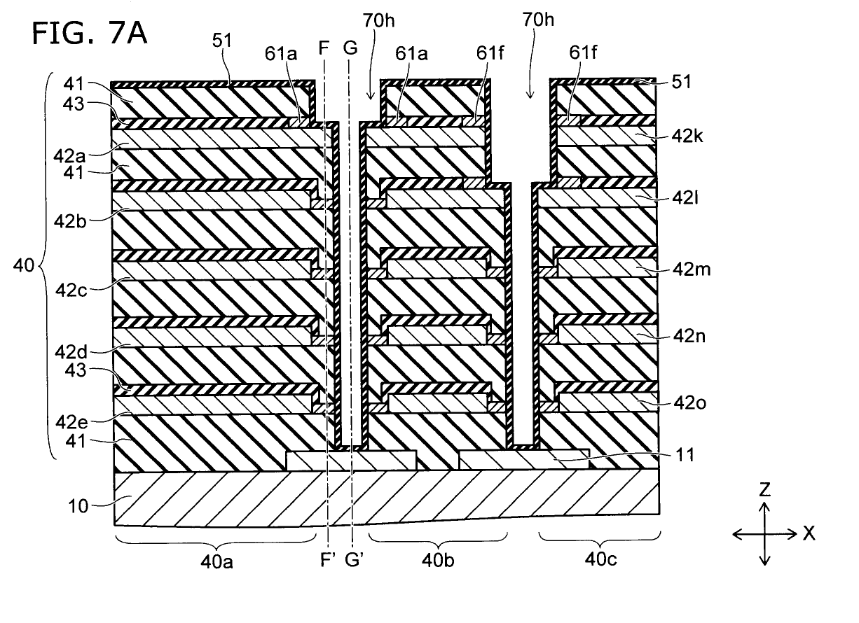

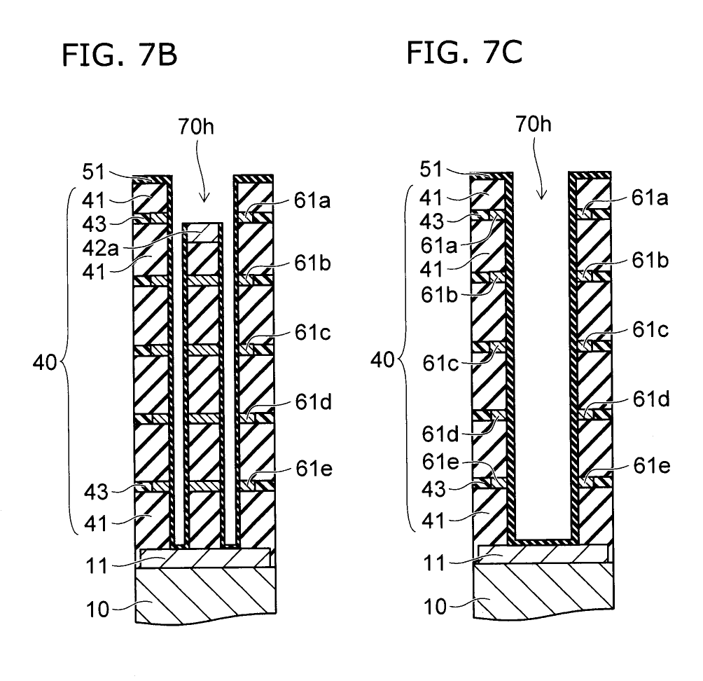

As shown in FIGS. 7A to 7C, the insulating films 51 are conformally formed on the inner walls (the sidewalls and the bottoms) of the holes 70h and the stacked body 40. As a method of forming the insulating films 51, for example, an ALD method (Atomic Layer Deposition) is used. The insulating films 51 include, for example, silicon oxide films.

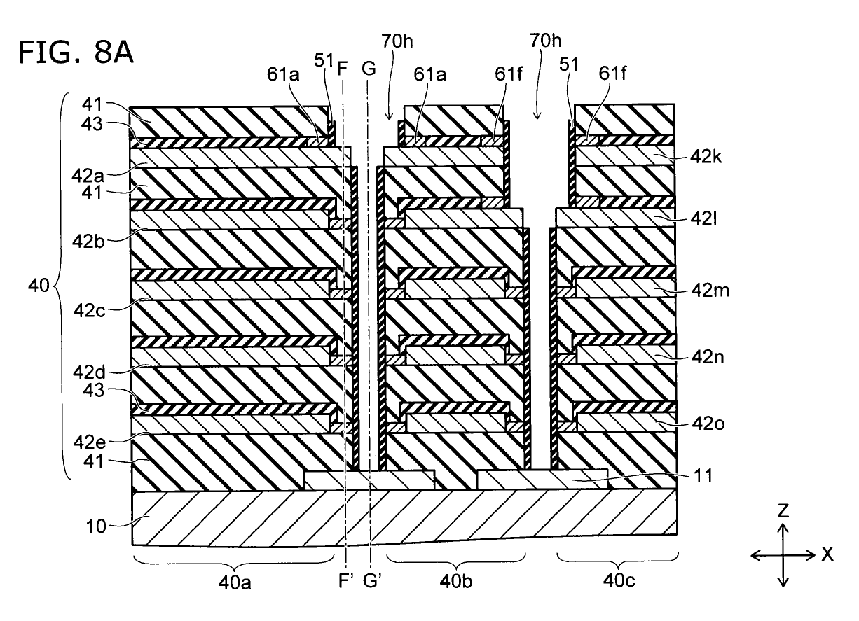

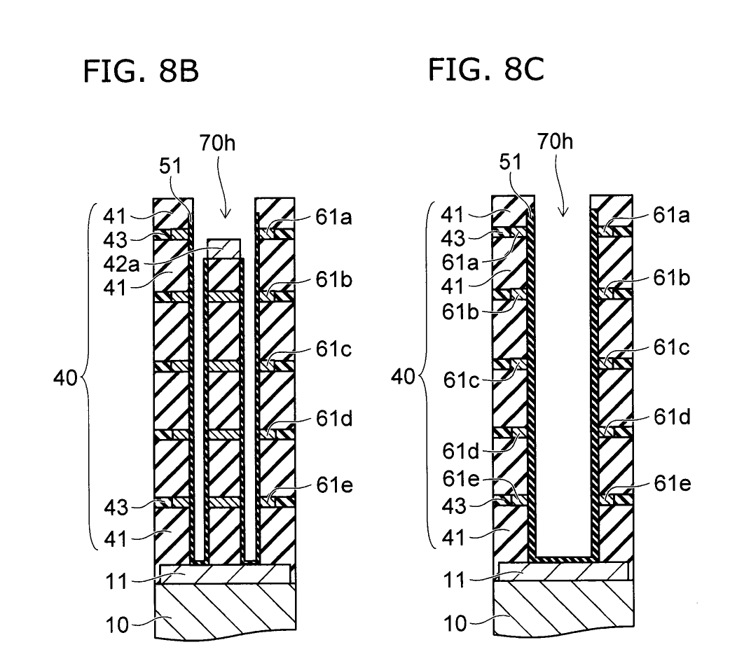

As shown in FIGS. 8A to 8C, the insulating films 51 formed on the upper surfaces and the side surfaces of the interconnect layers 42, in which the spaces 46 are formed, are removed. For example, the insulating films 51 formed on the interconnect layers 42 on both the sides of the spaces 46 are removed to expose the upper surfaces and the side surfaces of the interconnect layers 42 in the holes 70h. The insulating films 51 formed on the stacked body 40 are removed by, for example, etching using hydrochloric acid. The interconnect layers 42 in which the spaces 45 are formed are not exposed in the holes 70h. The plurality of conductive layers 61 is not exposed in the holes 70h.

An example of a layout of the stacked structure 100 of the embodiment is described with reference to FIGS. 9A to 9E.

FIG. 9A is a schematic plan view showing an example of a layout of the semiconductor device of the embodiment. FIG. 9B is an enlarged schematic plan view of a part of FIG. 9A. FIG. 9C is a schematic sectional view of a lower layer shown in FIGS. 9A and 9B. FIGS. 9D and 9E are schematic plan views corresponding to lines H-H′ and I-I′ in FIG. 9C.

As shown in FIG. 9A, the plurality of interconnect layers 42 of the stacked structure 100 is electrically connected to elements 2. The plurality of interconnect layers 42 is electrically connected to the control portion 3 via the pillars 50 and the lower layer interconnects 11. Therefore, the operating portions 2 are electrically connected to the control portion 3.

Stacked structures 100a and 100b are provided, for example, across an operating portion 2a. The operating portion 2a is electrically connected to the interconnect layers 42a and 42b extending in the X-direction from the stacked structures 100a and 100b. In the Y-direction, the interconnect layers 42a and 42b alternately extend to the operating portion 2a. For example, a plurality of stacked structures 100a and 100b may be provided alternately with the operating portions 2a and 2b.

As shown in FIGS. 9A and 9B, the pillars 50 only have to be provided in a range in which the pillars 50 do not overlap one another. The number of the provided pillars 50 may be any number. The diameter of the pillars 50 is larger than the width in the Y-direction of the interconnect layers 42. For example, the maximum diameter of the pillars 50 is 40 nm or more and 50 nm or less and the minimum diameter of the pillars 50 is 20 nm or more and 25 nm or less.

As shown in FIGS. 9C to 9E, the pillars 50a to 50d are in contact with lower layer interconnects 11a to 11d under the stacked body 40. For example, the lower layer interconnects 11a and 11d are provided on the lower layer interconnects 11b and 11c via the insulating layers 41. Therefore, the lower layer interconnects 11a to 11d are in contact with the control portion 3 while being separated from one another.

According to the embodiment, the conductive layers 61 are provided between the first interconnect portion 40a and the second interconnect portion 40b. The conductive layers 61 are electrically connected to the interconnect portions 40a and 40b. Therefore, for example, even when the interconnect layers 42 are separated according to the formation of the contact portions 52, it is possible to electrically connect the interconnect layers 42 separated from each other without providing new places where the interconnect layers 42 are connected.

Any interconnect layers 42 can be electrically connected to the lower layer interconnects 11 and the like via the contact portions 52. Consequently, it is possible to form contacts of the interconnect layers 42 without increasing an area more than necessary. It is possible to reduce the interconnect portions in size.

Further, it is possible to collectively form a plurality of pillars 50 without disconnecting the interconnecting layers 42. Therefore, compared with, for example, a contact forming method requiring the stacked body 40 having a step shape, it is possible to greatly reduce the area of the interconnect portions. It is unnecessary to perform a complicated process. It is possible to greatly reduce manufacturing costs.

For example, according to the reduction of the semiconductor device, it is likely that the resistance of the interconnects increases. In particular, when there is a region where the contact with the lower layer interconnects and the like is far, there are concerns about deterioration in characteristics, limitation of a layout of the interconnects, and the like.

On the other hand, according to the embodiment, it is possible to reduce the distance between the interconnect layers 42 and the lower layer interconnects. Further, the plurality of pillars 50 can be provided in a range in which the pillars 50 do not overlap one another. A plurality of lower layer interconnects 11 connected to the pillars 50 can be provided at different heights. Therefore, even when the pillars 50 are excessively densely provided, design rules for the lower layer interconnects 11 can be relaxed. It is unnecessary to increase the area more than necessary. It is possible to reduce the interconnect portions in size.

The thickness W1 of the conductive layers 61 is smaller than the thickness W2 of the plurality of interconnect layers 42. Therefore, it is possible to form the conductive layers 61 without increasing the volume of the entire stacked structure 100. It is possible to reduce the interconnect portions in size.

Note that the number of stacked layers and the disposition of the interconnect layers 42a to 42o shown in the figures are examples. The number of stacked layers and the disposition of the interconnect layers 42 are optional. The interconnect layers 42a to 42o may extend in the Y-direction. For example, in the first interconnect portion 40a, the interconnect layer 42a may extend in a direction different from a direction in which the interconnect layer 42b extends. Width W7 in the Y-direction of the interconnect layers 42 of the embodiment is less than 30 nm.

### Second Embodiment

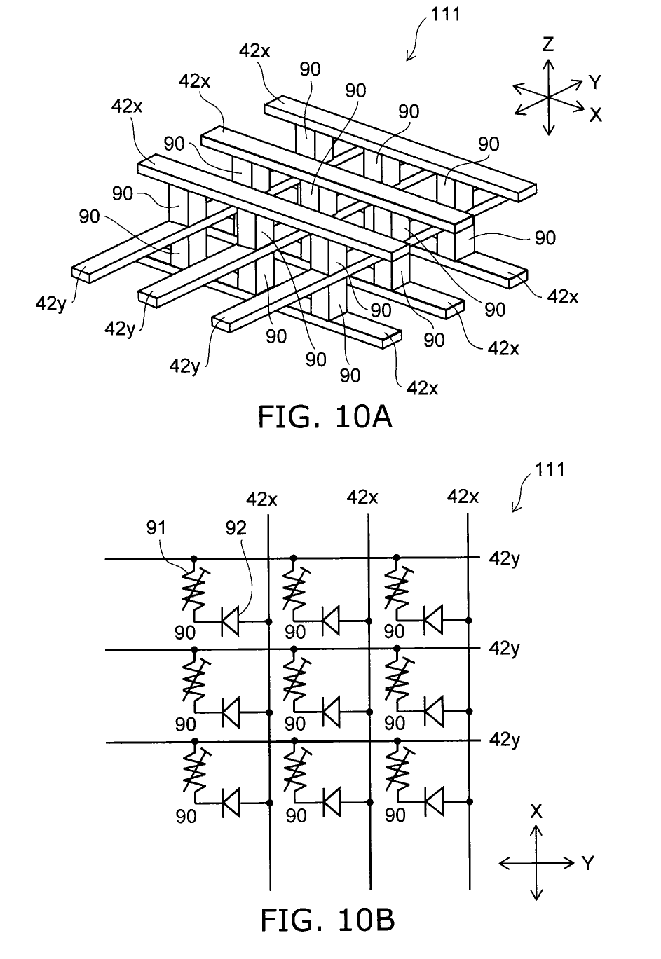

FIG. 10A is a schematic perspective view of a memory cell portion 111 of a semiconductor device in a second embodiment. FIG. 10B is a circuit diagram of the memory cell portion 111 in the second embodiment.

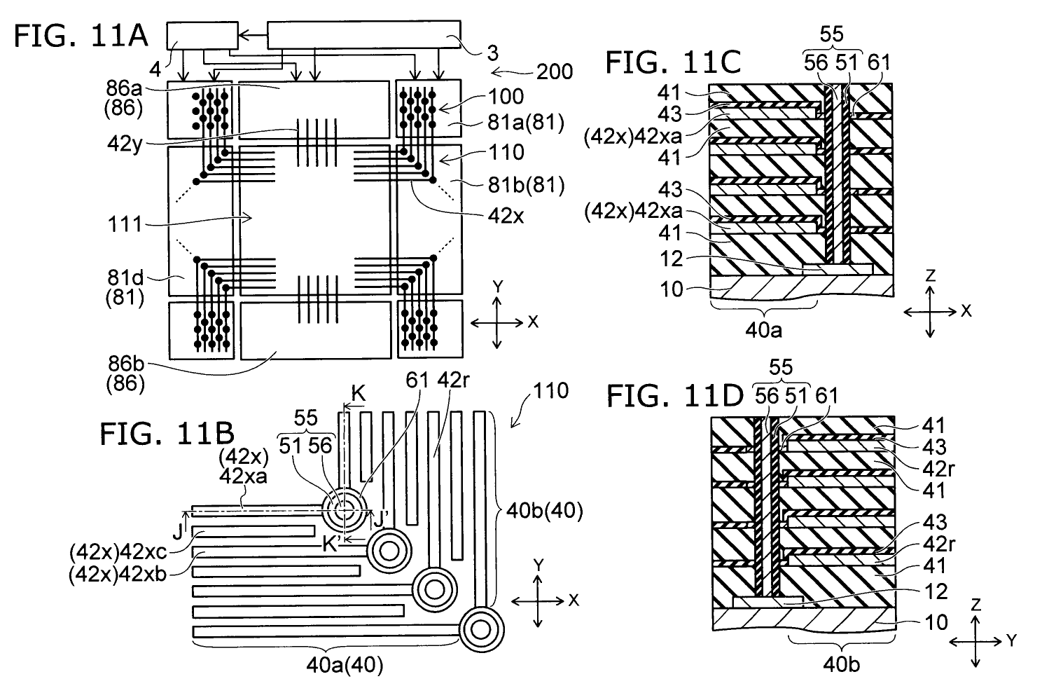

FIG. 11A is a schematic plan view of a semiconductor device 200 of the embodiment. FIG. 11B is an enlarged schematic plan view of a part of a stacked structure 110 of FIG. 11A. FIGS. 11C and 11D are schematic sectional views corresponding to lines J-J′ and K-K′ in FIG. 11B.

Note that, in the embodiment, the memory cell portion 111 is connected to the stacked structures 100 and 110. However, as in the first embodiment, a form of elements connected to the stacked structures 100 and 110 is optional. Description of structures same as the structures in the first embodiment is omitted.

As shown in FIG. 11A, the semiconductor device 200 of the embodiment includes the memory cell portion 111, the control portion 3, a power supply portion 4, a first decoder 81, a second decoder 86, and the stacked structures 100 and 110.

The control portion 3 controls the operation of the memory cell portion 111. The control portion 3 performs control such as a set operation, a reset operation, and readout operation for the memory cell portion 111 via the first decoder 81 and the second decoder 86. The power supply portion 4 supplies voltages to the portions on the basis of a signal received from the control portion 3.

For example, the power supply portion 4 supplies voltages to the first decoder 81 and the second decoder 86. With the voltages, the set operation, the reset operation, the readout operation, and the like for the memory cell portion 111 are executed.

The first decoder 81 is electrically connected to interconnect layers 42x extending in the X-direction of the memory cell portion 111. The second decoder 86 is electrically connected to interconnect layers 42y extending in the Y-direction of the memory cell portion 111. The decoders 81 and 86 apply a predetermined voltage to selected respective portions among a plurality of interconnect layers 42x and 42y. Consequently, rewriting and readout of information stored in a selected memory portion 91 can be performed.

As shown in FIG. 10A, the semiconductor device 200 of the embodiment includes the memory cell portion 111 of a cross point type. In the memory cell portion 111, the plurality of interconnect layers 42x (bit lines) extending in the X-direction and the plurality of interconnect layers 42y (word lines) extending in the Y-direction are provided. The plurality of interconnect layers 42x and 42y are alternately stacked via insulating films. The interconnect layers 42x are not in contact with one another. The interconnect layers 42y are not in contact with one another. The interconnect layers 42x and the interconnect layers 42y are not in contact with each other.

Pillars 90 extending in the Z-direction are provided on nearest contact lines of the interconnect layers 42x and the interconnect layers 42y. The pillars 90 are provided between the interconnect layers 42x and the interconnect layers 42y.

As shown in FIG. 10B, in one pillar 90, a memory portion 91 and a diode 92 are provided.

As shown in FIG. 11A, the interconnect layers 42x and 42y of the memory cell portion 111 extend to the first decoder 81 and the second decoder 86. For example, the plurality of interconnect layers 42x extends to at least one of first decoders 81b and 81d in two places provided across the memory cell portion 111. The first decoder 81 includes a lead portion 81a and a connecting portion 81b. The stacked structure 100 same as the stacked structure 100 in the first embodiment is provided on the lead portion 81a. The stacked structure 100 is electrically connected to the lead portion 81a and the control portion 3 via the contact portions 52.

The stacked structure 110 is provided on the connecting portion 81b. The stacked structure 100 is electrically connected to the memory cell portion 111 via the stacked structure 110. That is, the memory cell portion 111 is electrically connected to the control portion 3 via the stacked structures 100 and 110.

The second decoder 86 has a configuration same as the configuration of the first decoder 81. Therefore, description of the second decoder 86 is omitted.

As shown in FIGS. 11B to 11D, the stacked body 40, the pillars 55, and the plurality of conductive layers 61 are provided in the stacked structure 110.

The stacked body 40 includes the first interconnect portion 40a and the second interconnect portion 40b. The first interconnect portion 40a includes the plurality of interconnect layers 42x extending from the memory cell portion 111. The second interconnect portion 40b includes a plurality of interconnect layers 42r extending to the lead portion 81a in the Y-direction.

The plurality of conductive layers 61 is provided between the interconnect portions 40a and 40b adjacent to each other. The plurality of conductive layers 61 is in contact with the plurality of interconnect layers 42x and 42r adjacent to one another. The plurality of conductive layers 61 is separated from one another in the Z-direction.

The pillars 55 are provided between the first interconnect portion 40a and the second interconnect portion 40b. The side surfaces of the pillars 55 are surrounded by the plurality of conductive layers 61. The numbers of stacked layers of the interconnect layers 42x and 42r of the first interconnect portion 40a and the second interconnect portion 40b are the same.

The pillars 55 include insulating films 51 and core films 56. The insulating films 51 are provided on the side surfaces of the pillars 55 and continuously extend in the Z-direction. The insulating films 51 cover side surfaces of the respective plurality of interconnect layers 42x and 42r that are in contact with the pillars.

The core films 56 are provided on the inner sides of the insulating films 51 and separated from the plurality of interconnect layers 42. The core films 56 include metal such as tungsten and may be insulating films. The pillars 55 may be connected to, for example, interconnects provided above and below the pillars 55. The interconnects above and below the pillars 55 may be electrically connected via the core films 56. For example, as in the first embodiment, the core films 56 may be in contact with the interconnect layers 42. In that case, the pillars 55 have the shape of the pillars 50 shown in FIGS. 1A to 1F.

As shown in FIG. 11B, for example, the first interconnect portion 40a includes interconnect layers 42xa, 42xb, and 42xc (a first interconnect layer, a second interconnect layer, and a third interconnect layer) each electrically connected to the memory cell portion 111. The interconnect layer 42xb is separated from the interconnect layer 42xa in the Y-direction. The interconnect layer 42xc is provided between the interconnect layer 42xa and the interconnect layer 42xb. The interconnect layers 42xa and 42xb are electrically connected to the second interconnect portion 40b via the plurality of conductive layers 61. On the other hand, the interconnect layer 42xc is not electrically connected to the second interconnect portion 40b. That is, the interconnect layers 42x provided side by side in the Y-direction of the first interconnect portion 40a are electrically connected to the second interconnect portion 40b in every other layer.

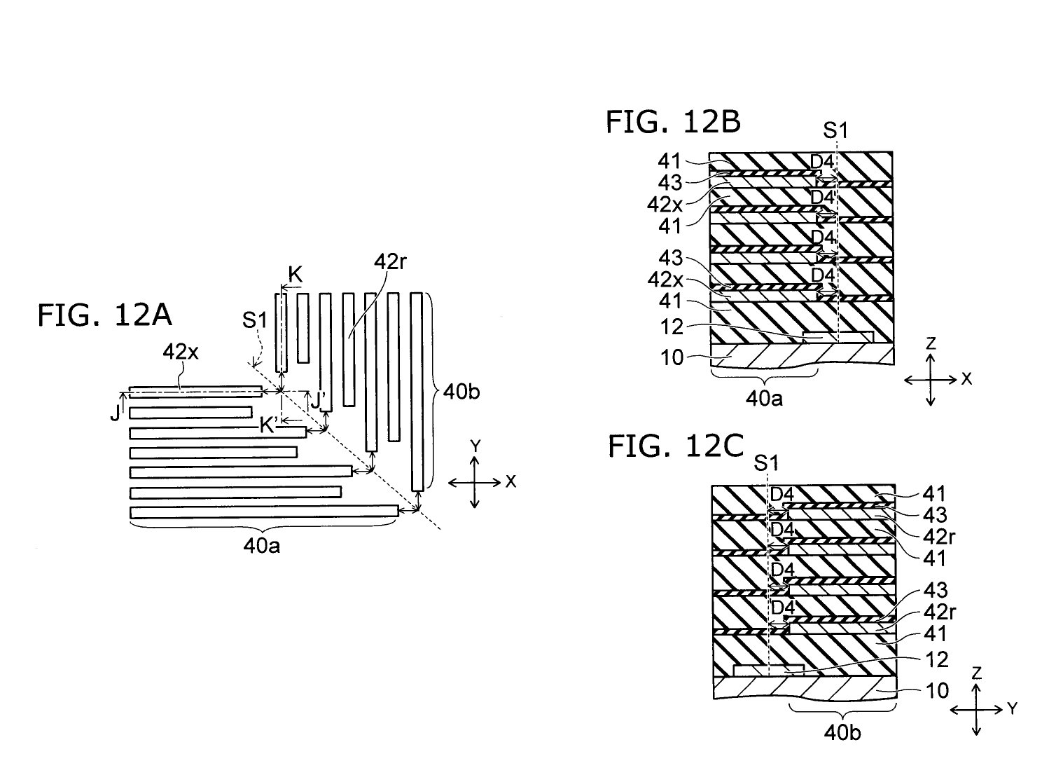

A method of manufacturing a semiconductor device of the embodiment is described with reference to FIGS. 12A to 18C.

FIGS. 12A, 13A, 14A, 15A, 16A, 17A, and 18A are schematic plan views.

FIGS. 12B, 13B, 14B, 15B, 16B, 17B, and 18B are schematic sectional views corresponding to lines J-J′ in FIGS. 12A, 13A, 14A, 15A, 16A, 17A, and 18A. FIGS. 12C, 13C, 14C, 15C, 16C, 17C, and 18C are schematic sectional views corresponding to lines K-K′ in FIGS. 12A, 13A, 14A, 15A, 16A, 17A, and 18A.

Note that the stacked structure 110 described below may be formed in a process same as the process of the stacked structure 100.

As shown in FIGS. 12A to 12C, a under layer 12 and the stacked body 40 are formed on the substrate 10. The stacked body 40 includes the plurality of insulating layers 41 and 43 and the plurality of interconnect layers 42. The under layer 12 is used as an etching stopper. The under layer 12 may be, for example, the lower layer interconnect 11.

In the formation of the stacked body 40, the insulating layers 41 are formed on the substrate 10. The interconnect layers 42 are formed on the insulating layers 41. The interconnect layers 42 include the interconnect layers 42x separated from one another in the Y-direction and extending in the X-direction, and the interconnect layers 42r separated from one another in the X-direction and extending in the Y-direction. The interconnect layers 42x and 42r are formed separately from each other. A pair of interconnect layers 42x and 42r electrically connected on a boundary S1 later forms an end in a position of the distance D4 from the boundary S1. The interconnect layers 42x and 42r are not electrically connected on the boundary S1 and form ends in positions further separated from the boundary S1 than the distance D4.

Thereafter, the insulating layers 43 are conformally formed on the upper surfaces of the interconnect layers 42 and the insulating layers 41. The insulating layers 41 are formed on the insulating layers 43. The upper surfaces of the insulating layers 41 are uniformly formed on the XY plane.

The insulating layers 41, the interconnect layers 42x and 42r, and the insulating layers 43 are formed in order and the insulating layer 41 is formed in the top layer, whereby the stacked body 40 is formed. The number of stacked layers of the stacked body 40 may be any number. The stacked body 40 includes the first interconnect portion 40a and the second interconnect portion 40b separated from each other across the boundary S1.

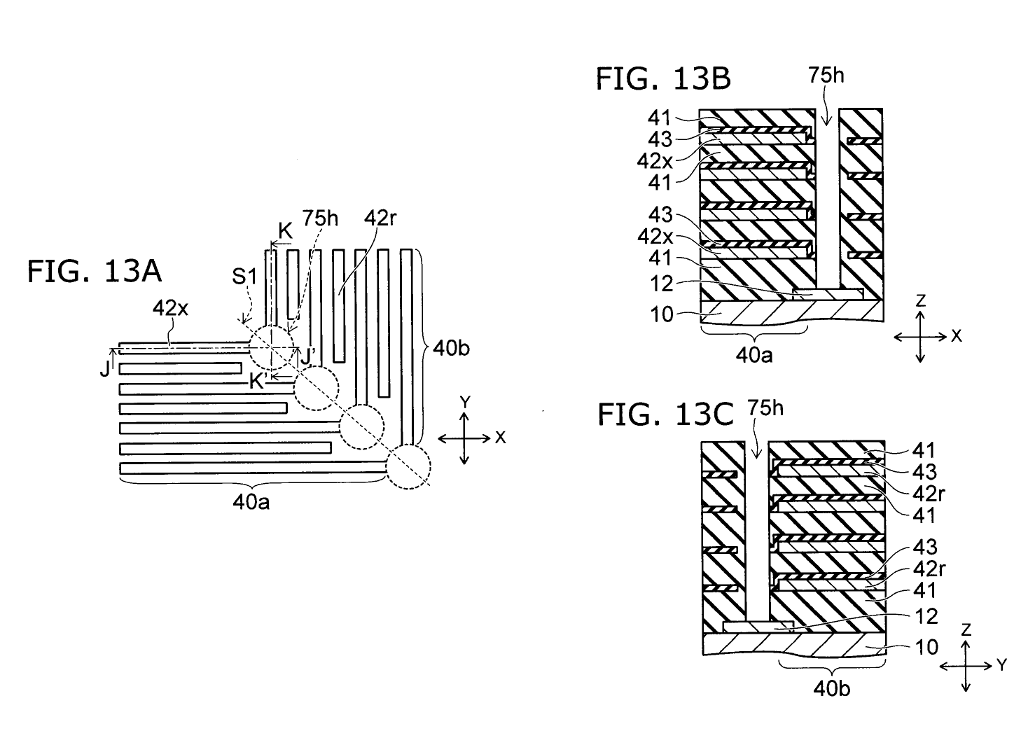

As shown in FIGS. 13A to 13C, holes 75h piercing through the stacked body 40 and reaching the under layer 12 are formed on the boundary S1. The side surfaces of the insulating layers 43 and the upper surface of the under layer 12 are exposed in the holes 75h. The interconnect layers 42x and 42r are not exposed in the holes 75h. The holes 75h are formed by, for example, the RIE method. The under layer 12 is used as an etching stopper.

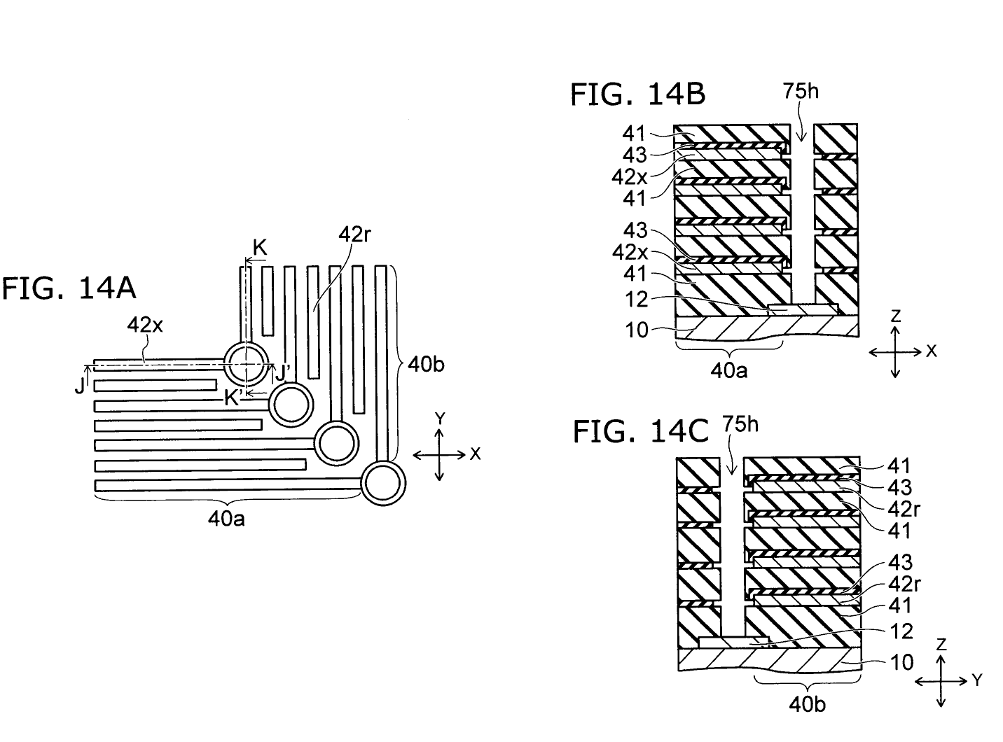

As shown in FIGS. 14A to 14C, the insulating layers 43 exposed in the holes 75h are retracted. Consequently, the interconnect layers 42 are exposed in the holes 75h.

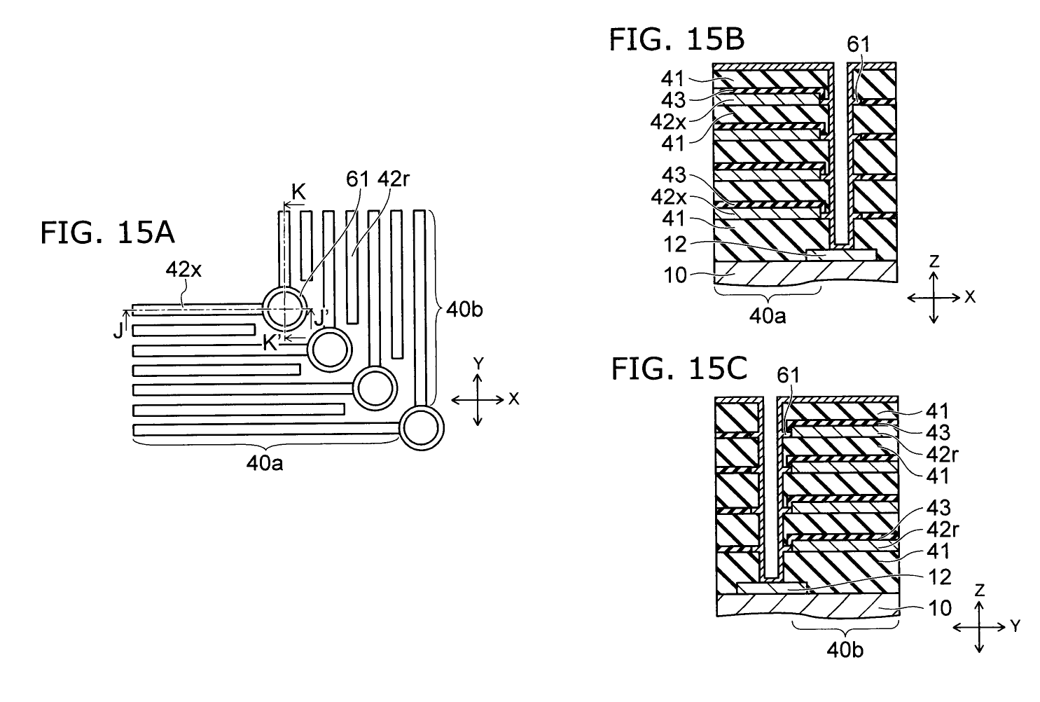

As shown in FIGS. 15A to 15C, the plurality of conductive layers 61 is formed in respective layers in retracted portions of the insulating layers 43. As a method of forming the conductive layers 61, for example, the CVD method is used to form films (e.g., titanium nitride) having electric conductivity in the retracted portions of the insulating layers 43 and the inner walls of the holes 75h through the holes 75h. Subsequently, for example, the CVD method is used to form metal films (e.g., tungsten) on the inner sides of the films having electric conductivity. The conductive layers 61 are formed.

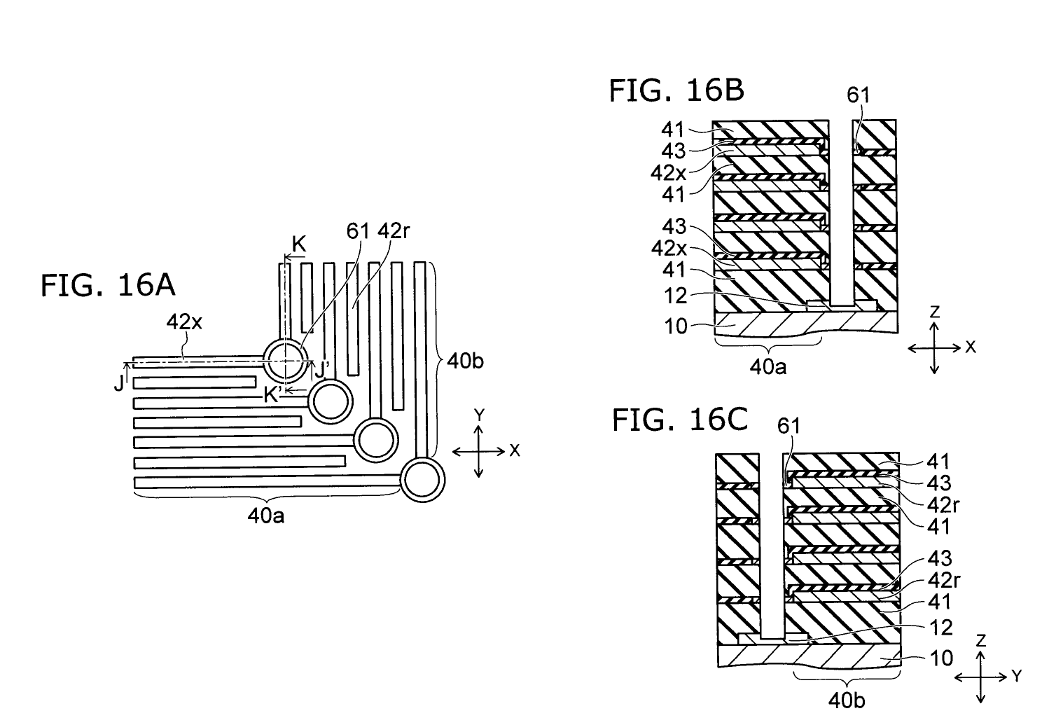

As shown in FIGS. 16A to 16C, the conductive layers 61 formed on the sidewalls of the holes 75h, the stacked body 40, and the like are removed using, for example, the RIE method. Consequently, the interconnect layers 42a and 42b in the respective layers are electrically connected via the conductive layers 61.

The plurality of conductive layers 61 is in contact with the interconnect layers 42x and 42y separated across the holes 75h. Therefore, a pair of interconnect layers 42x and 42y separated across the hole 75h is electrically connected via the conductive layers 61. The side surfaces of the conductive layers 61 are exposed in the holes 75h.

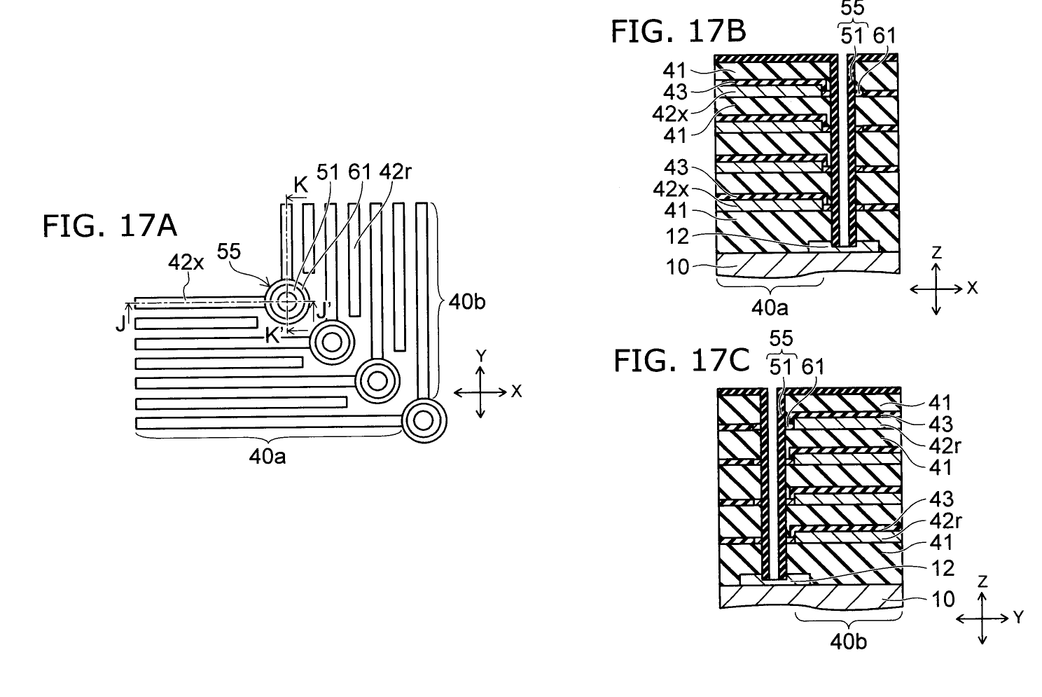

As shown in FIGS. 17A to 17C, the insulating films 51 are conformally formed on the inner walls of the holes 75h and the stacked body 40. As a method of forming the insulating films 51, for example, an ALD method is used. The insulating films 51 include, for example, silicon oxide films. For example, the insulating films 51 may be formed in the holes 75h without a gap.

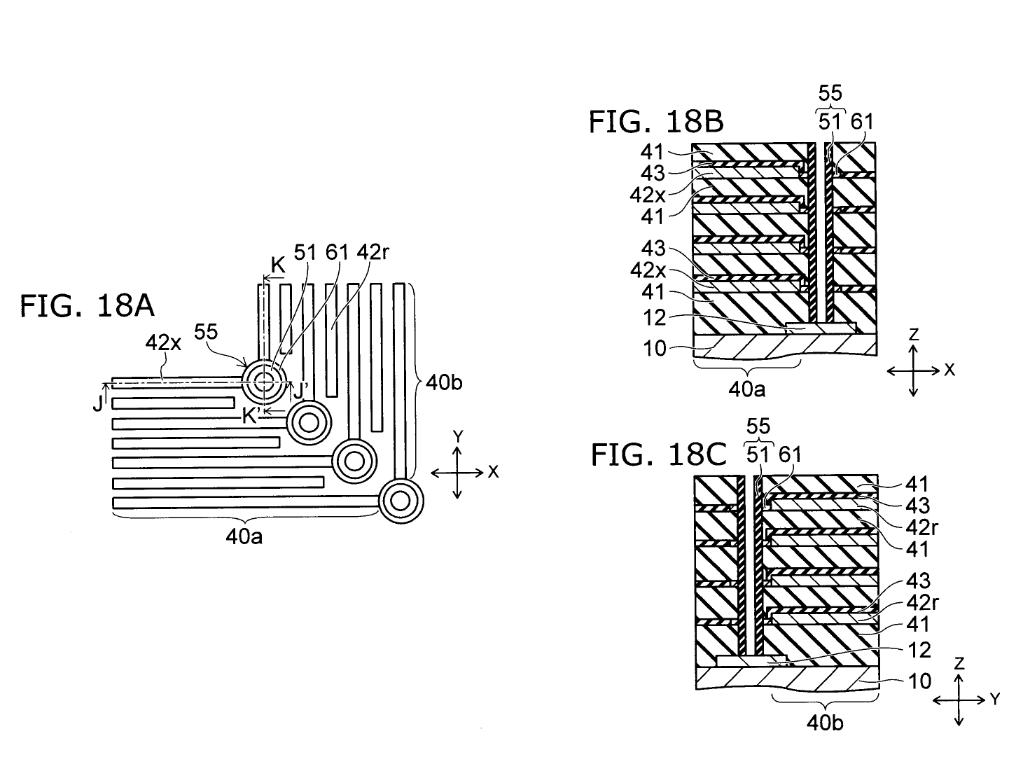

As shown in FIGS. 18A to 18C, the insulating films 51 formed on the stacked body 40 are removed using, for example, the RIE method.

Subsequently, as shown in FIGS. 11B to 11D, the core films 56 are formed on the inner sides of the insulating films 51. Thereafter, connection to the control portion 3 and the like is performed. The semiconductor device of the embodiment is formed.

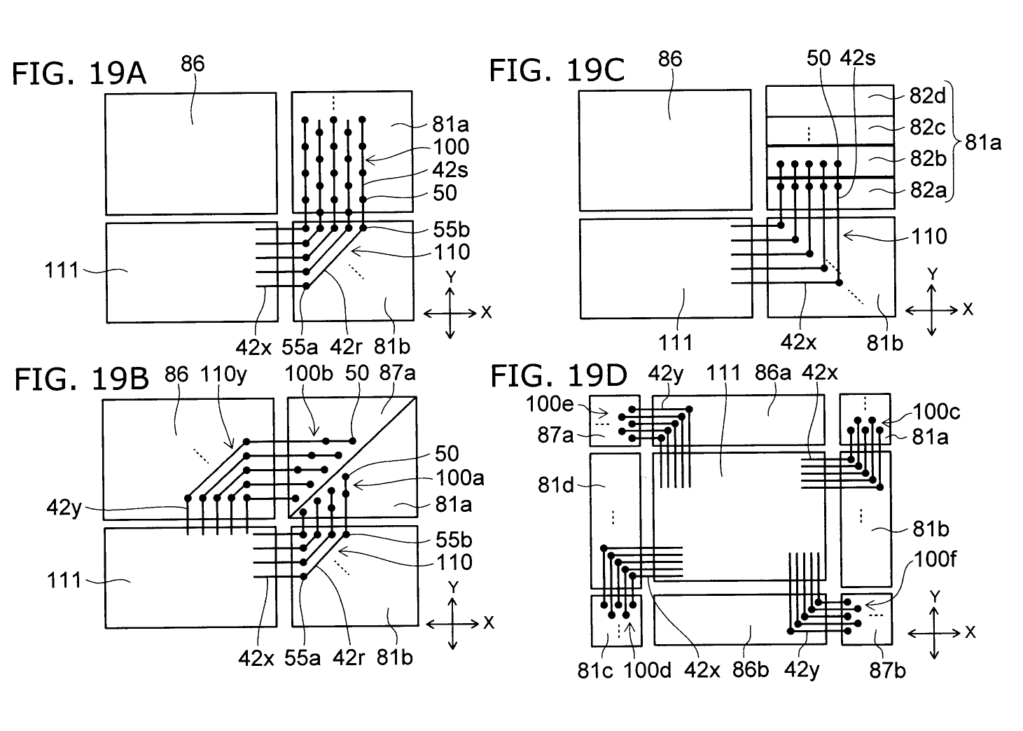

An example of a layout of the stacked structures 100 and 110 of the embodiment is described with reference to FIGS. 19A to 19D. Note that, when layouts of the second decoder 86 and the first decoder 81 are the same in directions other than a direction in which the interconnect layers extend, description of the layouts is omitted.

FIGS. 19A to 19D are schematic plan views showing the example of the layout of the stacked structures 100 and 110 of the embodiment.

As shown in FIGS. 19A and 19B, the stacked structure 110 includes pillars 55a and 55b in the connecting portion 81b. The plurality of interconnect layers 42x extending from the memory cell portion 111 is in contact with the plurality of conductive layers 61 provided around the pillars 55a. A plurality of interconnect layers 42s extending from the stacked structure 100 is in contact with the plurality of conductive layers 61 provided around the pillars 55b. Consequently, the memory cell portion 111 is electrically connected to the stacked structure 100 via the stacked structure 110.

The plurality of interconnect layers 42r of the stacked structure 110 extends in a direction crossing a direction in which the plurality of interconnect layers 42x of the memory cell portion 111 extends and a direction in which the plurality of interconnect layers 42s of the stacked structure 100 extends. The interconnect layers 42r have, for example, a tilt of 45 degrees with respect to the directions in which the interconnect layers 42x and the interconnect layers 42s extend.

The plurality of interconnect layers 42x of the memory cell portion 111 is electrically connected to the pillars 50 of the stacked structure 100. The pillars 50 are electrically connected to the control portion 3 via the lower layer interconnect 11 provided in the lead portion 81a.

As shown in FIG. 19A, in the lead portion 81a, the plurality of pillars 50 included in the stacked structure 100 is provided. The plurality of pillars 50 is provided, for example, in a hound's-tooth check pattern.

As shown in FIG. 19B, in the lead portion 81a, the stacked structure 100a and the stacked structure 100b are provided. The stacked structure 100a is electrically connected to the interconnect layers 42x in the X-direction of the memory cell portion 111 via a stacked structure 110x. The stacked structure 100b is electrically connected to the interconnect layers 42y in the Y-direction of the memory cell portion 111 via a stacked structure 110y provided in the second decoder 86.

As shown in FIG. 19C, a plurality of lead regions 82a to 82d is provided in the lead portion 81a. The pillars 50, which are respectively in contact with the interconnect layers 42s in different layers, are in contact with the lead regions 82a to 82d. Therefore, the lead regions 82a to 82d are electrically connected to the interconnect layers 42s in each layer.

As shown in FIG. 19D, in lead portions 81a and 81c, stacked structures 100c and 100d electrically connected to the interconnect layers 42x in the X-direction of the memory cell portion 111 are provided. That is, the interconnect layers 42x of the memory cell portion 111 are electrically connected to one of the stacked structures 100c and 100d.

According to the embodiment, as in the first embodiment, the plurality of conductive layers 61 is provided between the first interconnect portion 40a and the second interconnect portion 40b. The plurality of conductive layers 61 is electrically connected to the plurality of interconnect layers 42x extending in the X-direction and the plurality of interconnect layers 42r extending in the Y-direction. For example, when the interconnect layers 42 extending in different directions are integrally formed, it is difficult to form the interconnect layers 42 according to refining of the interconnect layers 42. On the other hand, by providing the plurality of conductive layers 61, it is possible to easily form the interconnect layers 42x and 42r extending in different directions. It is possible to reduce the interconnect portions in size. By using the interconnect layers 42 extending in different directions, it is possible to effectively use the areas of the decoders 81 and 86 and suppress an increase in the areas involved in an increase of interconnects.

Further, by providing the plurality of conductive layers 61 that connect the interconnect layers 42x and 42r, it is possible to increase a degree of freedom of the layout of the interconnect layers 42. It is possible to form interconnects short.

As in the first embodiment, the contact portions 52 are provided in the stacked structure 100. Consequently, it is possible to electrically connect any interconnect layers 42 to the lower layer interconnects 11 and the like. Consequently, it is possible to form contacts of the interconnect layers 42 without increasing an area more than necessary. It is possible to reduce the interconnect portions in size.

Further, it is possible to collectively form the plurality of pillars 50 without disconnecting the interconnect layers 42. Therefore, compared with, for example, a contact forming method requiring the stacked body 40 having a step shape, it is possible to greatly reduce the area of the interconnect portions. It is unnecessary to perform a complicated process. It is possible to greatly reduce manufacturing costs.

It is possible to reduce the distance between the interconnect layers 42 and the lower layer interconnects. Further, the plurality of pillars 50 can be provided in a range in which the pillars 50 do not overlap one another. The plurality of lower layer interconnects 11 connected to the pillars 50 can be provided at different heights. Therefore, even when the pillars 50 are excessively densely provided, design rules for the lower layer interconnects 11 can be relaxed. It is unnecessary to increase the area more than necessary. It is possible to reduce the interconnect portions in size.

The thickness W1 of the plurality of conductive layers 61 is smaller than the thickness W2 of the plurality of interconnect layers 42. Therefore, it is possible to form the conductive layers 61 without increasing the volume of the entire stacked structure 100. It is possible to reduce the interconnect portions in size.

Note that in the connecting portions of the decoders, contacts may be provided as the lead portions. In this case, the contacts may be connected to TFTs (thin film transistors) provided in the connecting portions.

### Third Embodiment

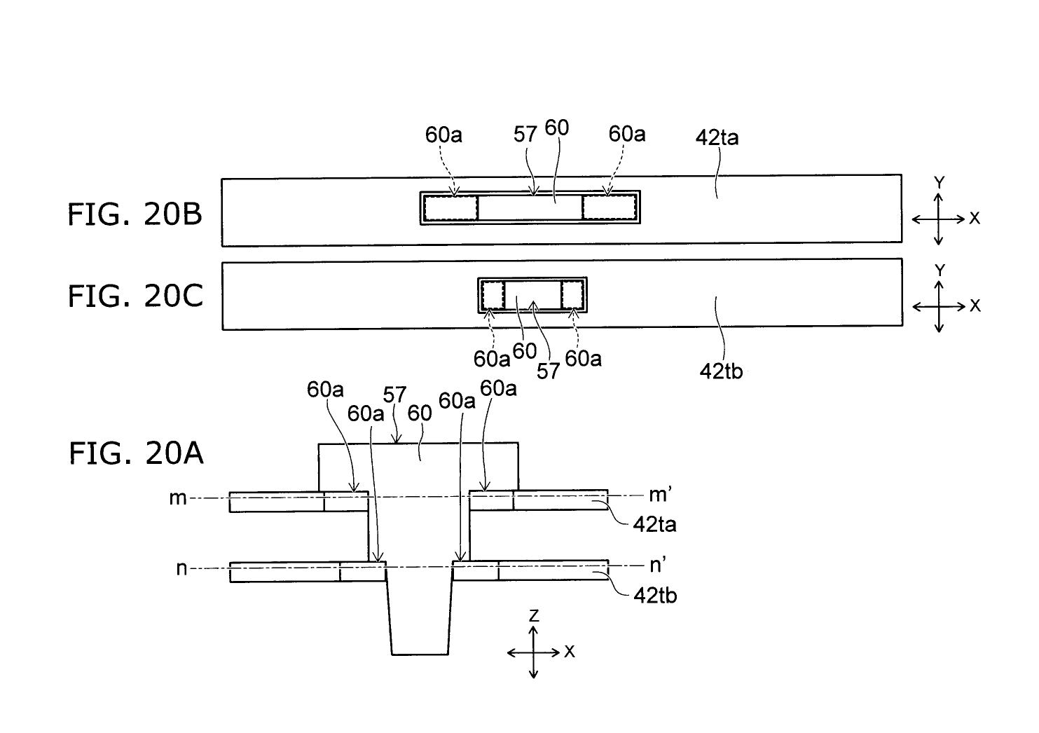

FIGS. 20A to 22C are schematic views showing the interconnect layers 42 of a stacked structure in a third embodiment.

The embodiment is different from the first and second embodiments in that the width in the Y-direction of interconnect layers 42t is large. The width in the Y-direction of interconnect layers 42ta and 42tb described below is, for example, 30 nm or more. The width of the interconnect layers in the first and second embodiments is, for example, less than 30 nm. Therefore, pillars 57 are provided in the interconnect layers 42t. The interconnect layers 42 continuously extend in the X-direction.

Note that, as in the first and second embodiments, a form of elements connected to the interconnect layers 42 of the stacked structure is optional. Description of a structure same as the structure in the first and second embodiments is omitted.

FIGS. 20A, 21A, and 22A are schematic sectional views of the interconnect layers 42 of the stacked structure. FIGS. 20B, 21B, and 22B are schematic plan views corresponding to lines m-m′ in FIGS. 20A, 21A, and 22A. FIGS. 20C, 21C, and 22C are schematic plan views corresponding to lines n-n′ in FIGS. 20A, 21A, and 22A.

As shown in FIGS. 20A to 22C, the interconnect layer 42ta (a first interconnect) and the interconnect layer 42tb (a second interconnect) extend in the X-direction. The interconnect layer 42ta is separated from the interconnect layer 42tb.

In the interconnect layers 42t, the pillars 57 extending in the Z-direction are provided. Conductive portions 60 are provided in the pillars 57. The conductive portions 60 extend in the Z-direction and are in contact with, for example, the substrate 10.

The conductive portions 60 are surrounded by the interconnect layers 42ta and 42tb.

The interconnect layers 42ta and 42tb include first surfaces 60a that are in contact with the conductive portions 60. The first surfaces 60a are provided on the upper surfaces of the interconnect layers 42ta and 42tb. The conductive portions 60 are in contact with, for example, the lower layer interconnects 11 of the substrate 10 shown in FIG. 1A and is electrically connected to the control portion 3.

As shown in FIGS. 20A to 20C, the conductive portions 60 are in contact with the interconnect layers 42ta and 42tb in two layers. Therefore, the interconnect layer 42ta is electrically connected to the interconnect layer 42tb via the conductive portions 60.

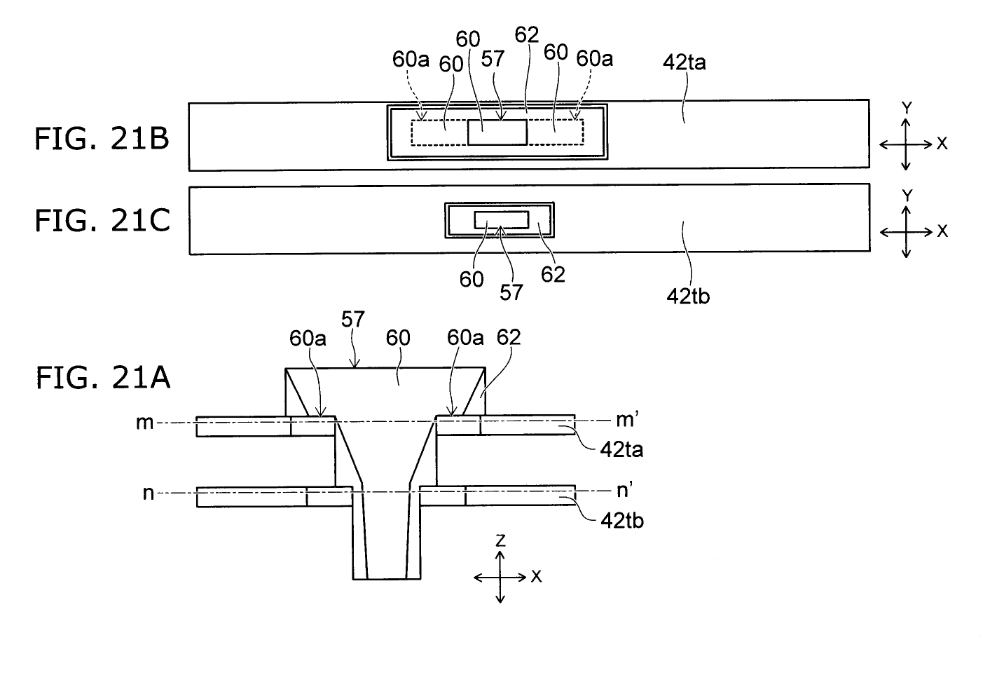

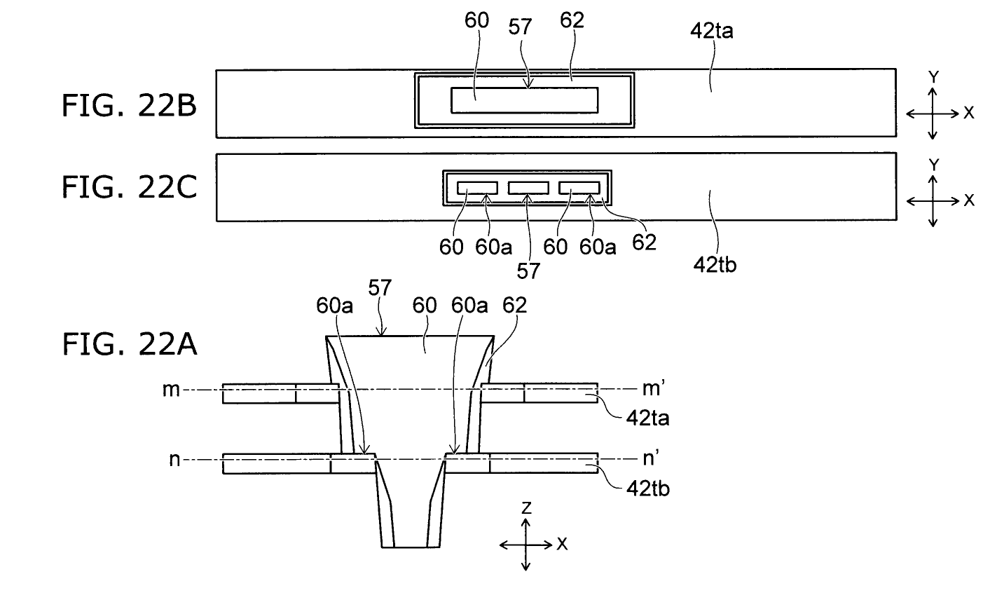

As shown in FIGS. 21A to 22C, insulating films 62 are provided on the side surfaces of the conductive portions 60. The insulating films 62 are provided between the conductive portions 60 and the side surfaces in the X-direction of the interconnect layers 42ta and 42tb.

As shown in FIGS. 21A, 21B, 22A, and 22C, the conductive portions 60 include first surfaces 60a that are in contact with the upper surfaces of the interconnect layers 42ta and 42tb. On the other hand, as shown in FIGS. 21A, 21C, 22A, and 21B, the conductive portions 60 are separated from the interconnect layers 42ta and 42tb. The insulating films 62 are provided between the conductive portions 60 and at least one of the upper surface of the interconnect layer 42ta and the upper surface of the interconnect layer 42tb. Therefore, by providing the insulating films 62, electric connection portions between the conductive portions 60 and the interconnect layers 42ta and 42tb can be selectively provided.

According to the embodiment, as in the first and second embodiments, the conductive portions 60 electrically connected to the interconnect layers 42ta and 42tb are provided. Consequently, it is possible to electrically connect any interconnect layers 42ta and 42tb to the lower layer interconnects 11 and the like. The conductive portions 60 can be formed without limiting the structure of the stacked body 40 to a step shape or the like. Therefore, it is possible to greatly reduce the interconnect portions in size and greatly reduce manufacturing costs.

Further, as in the first and second embodiments, the conductive portions 60 can be provided not to overlap the conductive portions 60 provided in other interconnect layers 42t. The plurality of lower layer interconnects 11 connected to the conductive portions 60 can be provided in different heights. Therefore, even when the pillars 57 are excessively densely provided, it is unnecessary to increase the area of the lower layer interconnects 11 more than necessary. It is possible to reduce the interconnect portions in size.

For example, the width of the plurality of interconnect layers 42 is sometimes set smaller than the width of the conductive portions 60. In this case, the width of the interconnect layers 42 may be set large only in portions where the conductive portions 60 are provided. Consequently, it is possible to provide the conductive portions 60 without substantially changing the structure of the stacked body 40. It is possible to reduce the interconnect portions in size.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a substrate;
a first interconnect portion provided on the substrate and including a plurality of interconnect layers separately stacked each other;
a second interconnect portion provided separately from the first interconnect portion on the substrate and including the plurality of interconnect layers having a number of stacked layers same as a number of stacked layers of the first interconnect portion;
a first pillar provided adjacent to the first interconnect portion and the second interconnect portion and extending in a stacking direction of the plurality of interconnect layers; and
a plurality of conductive layers separately stacked each other, surrounding a side surface of the first pillar, and electrically connected to the first interconnect portion and the second interconnect portion.

2. The device according to claim 1, wherein
the first pillar includes:
a first insulating film provided on the side surface of the first pillar and extending in the stacking direction; and
a first contact portion provided on an inner side of the first insulating film, extending in the stacking direction, and having columnar shape,
the first interconnect portion includes a first interconnect provided relative to the first contact portion via the first insulating film,
the second interconnect portion includes a second interconnect separated from the first interconnect by a first distance and provided relative to the first contact portion via the first insulating film, and
the plurality of conductive layers includes a first conductive layer provided relative to the first contact portion via the first insulating film and being in contact with the first interconnect and the second interconnect.

3. The device according to claim 2, wherein
the first conductive layer includes:
a first periphery portion being in contact with a side surface of the first interconnect parallel to an extending direction of the first interconnect and a side surface of the second interconnect parallel to an extending direction of the second interconnect, the first periphery portion extending along a side surface of the first insulating film; and
a second periphery portion being in contact with a side surface opposed to the side surface being in contact with the first periphery portion of the first interconnect, and a side surface opposed to the side surface being in contact with the first periphery portion of the second interconnect, the second periphery portion extending along the side surface of the first insulating film and separated from the first periphery portion.

4. The device according to claim 3, wherein
the first interconnect portion includes a third interconnect provided between the first interconnect and the substrate and including a first end portion being in contact with the first contact portion,
the second interconnect portion includes a fourth interconnect provided between the second interconnect and the substrate, separated from the third interconnect by a second distance smaller than the first distance, and including a second end portion being in contact with the first contact portion,
the plurality of conductive layers includes a second conductive layer provided relative to the first contact portion via the first insulating film,
the second conductive layer includes:
a third periphery portion being in contact with a side surface separated from the first end portion of the third interconnect and a side surface separated from the second end portion of the fourth interconnect, the third periphery portion extending along the side surface of the first insulating film; and
a fourth periphery portion being in contact with a side surface opposed to the side surface being in contact with the third periphery portion of the third interconnect, and a side surface opposed to the side surface being in contact with the third periphery portion of the fourth interconnect, the fourth periphery portion extending along the side surface of the first insulating film and separated from the third periphery portion, and
the first insulating film is in contact with and provided integral with the third interconnect, the fourth interconnect, the third periphery portion, and the fourth periphery portion.

5. The device according to claim 2, wherein
the first conductive layer includes:
a first connecting portion provided in contact with a side surface crossing an extending direction of the first interconnect;
a second connecting portion separated from the first connecting portion and provided in contact with a side surface crossing an extending direction of the second interconnect;
a first periphery portion being in contact with the first connecting portion and the second connecting portion, and extending along a side surface of the first insulating film; and
a second periphery portion separated from the first periphery portion, being in contact with the first connecting portion and the second connecting portion, and extending along the side surface of the first insulating film,
the first connecting portion includes a first distal end portion extending in the extending direction of the first interconnect, the first distal end portion separated from the first periphery portion and the second periphery portion,
the second connecting portion includes a second distal end portion extending in the extending direction of the second interconnect, the second distal end portion separated from the first periphery portion, the second periphery portion, and the first distal end portion, and
the first insulating film is in contact with and provided integrally with the first periphery portion, the second periphery portion, the first distal end portion, and the second distal end portion.

6. The device according to claim 1, wherein
the first pillar includes:
a first insulating film provided on a side surface of the first pillar and extending in the stacking direction; and
a first contact portion provided on an inner side of the first insulating film, extending in the stacking direction, and having a columnar shape,
the first interconnect portion includes a first interconnect including a first end portion being in contact with the first contact portion,
the second interconnect portion includes a second interconnect including a second end portion being in contact with the first contact portion,
the plurality of conductive layers includes a first conductive layer provided relative to the first contact portion via the first insulating film,
the first conductive layer includes:
a first periphery portion being in contact with a side surface separated from the first end portion of the first interconnect and a side surface separated from the second end portion of the second interconnect, the first periphery portion extending along a side surface of the first insulating film; and
a second periphery portion being in contact with a side surface opposed to the side surface being in contact with the first periphery portion of the first interconnect and a side surface opposed to the side surface being in contact with the first periphery portion of the second interconnect, the second periphery portion extending along the side surface of the first insulating film and separated from the first periphery portion, and
the first insulating film is in contact with and provided integral with the first end portion, the second end portion, the first periphery portion, and the second periphery portion.

7. The device according to claim 1, wherein
the first interconnect portion includes:
a first interconnect provided on the substrate; and
a third interconnect provided between the first interconnect and the substrate,
the second interconnect portion includes:
a second interconnect provided on the substrate; and
a fourth interconnect provided between the second interconnect and the substrate,
the first pillar includes:
a first insulating film provided on the side surface of the first pillar and extending in the stacking direction; and
a first contact portion provided on an inner side of the first insulating film, extending in the stacking direction, and being in contact with the first interconnect and the second interconnect,
the plurality of conductive layer includes:
a first conductive layer being in contact with the first interconnect and the second interconnect, and extending along the side surface of the first insulating film; and
a second conductive layer being in contact with the third interconnect and the fourth interconnect, and extending along the side surface of the first insulating film.

8. The device according to claim 7, further comprising:
a third interconnect portion provided separately from the first interconnect portion and the second interconnect portion on the substrate and including the plurality of interconnect layers having a number of stacked layers same as a number of stacked layers of the first interconnect portion and the second interconnect portion; and
a second pillar provided adjacent to the second interconnect portion and the third interconnect portion and extending in the stacking direction, wherein
the third interconnect portion includes:
a fifth interconnect provided on the substrate; and
a sixth interconnect provided between the fifth interconnect and the substrate,
the second pillar includes:
a second insulating film provided on a side surface of the second pillar and extending in the stacking direction; and
a second contact portion provided on an inner side of the second insulating film, extending in the stacking direction, and being in contact with the fourth interconnect and the sixth interconnect,
the plurality of conductive layers includes:
a third conductive layer being in contact with the second interconnect and the fifth interconnect, the third conductive layer extending along the side surface of the second insulating film; and
a fourth conductive layer being in contact with the fourth interconnect and the sixth interconnect, the fourth conductive layer extending along the side surface of the second insulating film.

9. The device according to claim 8, wherein a distance between the fourth conductive layer and the second interconnect is smaller than a distance between the second conductive layer and the first interconnect.

10. The device according to claim 7, wherein the second conductive layer includes a material same as a material of the first conductive layer.

11. The device according to claim 1, further comprising an insulating layer provided in contact with upper surfaces of the plurality of interconnect layers, a side surface parallel to a extending direction of the plurality of interconnect layers and the plurality of conductive layers.

12. The device according to claim 7, wherein
the second interconnect is separated from the first interconnect by a second distance, and
the fourth interconnect is separated from the third interconnect by a first distance smaller than the second distance.

13. The device according to claim 1, wherein the first pillar includes a first insulating film provided on a side surface of the first pillar, continuously extending in the stacking direction, and covering a side surface of each of the plurality of interconnect layers being in contact with the first pillar.

14. The device according to claim 1, wherein the plurality of conductive layers is in contact with a side surfaces of the plurality of interconnect layers parallel to a first direction extending from the plurality of interconnect layers to the first pillar.

15. The device according to claim 1, wherein thickness of the plurality of conductive layers is thinner than thickness of the plurality of interconnect layers.

16. The device according to claim 1, wherein
the plurality of interconnect layers of the first interconnect portion extends in a first direction crossing the stacking direction, and
the plurality of interconnect layers of the second interconnect portion extends in a second direction crossing the stacking direction and the first direction.

17. The device according to claim 1, further comprising a plurality of memory cells electrically connected to the first interconnect portion, wherein
the first interconnect portion includes:
a first interconnect layer extending in a first direction crossing the stacking direction and electrically connected to the second interconnect portion via the plurality of conductive layers;
a second interconnect layer provided separately from the first interconnect layer in a second direction crossing the stacking direction and the first direction and electrically connected to the second interconnect portion via the plurality of conductive layers; and
a third interconnect layer provided between the first interconnect layer and the second interconnect layer and no electrically connected to the second interconnect portion.

18. The device according to claim 1, wherein a width of the plurality of interconnect layers is less than 30 nm in a second direction crossing each of the stacking direction and a first direction crossing the stacking direction,.

19. A semiconductor device comprising:
a substrate;
a first interconnect provided on the substrate and continuously extending in a first direction;
a second interconnect provided between the substrate and the first interconnect, separated from the first interconnect, and extending in the first direction; and
a conductive portion extending in a stacking direction from the first interconnect to the second interconnect, a side surface of the conductive portion provided in contact with the first interconnect and the second interconnect, the conductive portion being in contact with the first interconnect and the second interconnect.

20. A semiconductor device comprising:
a substrate;
a first interconnect provided on the substrate and continuously extending in a first direction;
a second interconnect provided between the substrate and the first interconnect, separated from the first interconnect, and extending in the first direction;
a conductive portion extending in a stacking direction from the first interconnect to the second interconnect, a side surface of the conductive portion provided in contact with the first interconnect and the second interconnect, the conductive portion being in contact with at least one of an upper surface of the first interconnect and an upper surface of the second interconnect; and
an insulating film provided between the side surface of the conductive portion and the first interconnect, and between the side surface of the conductive portion and the second interconnect, extending in the stacking direction, and being in contact with the upper surface of the first interconnect and the upper surface of the second interconnect.
